(19) United States
(12) Patent Application Publication
(10) Pub. No.: US 2026/0271722 A1
(43) Pub. Date: Sep. 10, 2026

(54) SYSTEM AND METHOD FOR COOLING AN ELECTRONIC DEVICE

(71) Applicant: Impact Cooling Inc., Birmingham, AL (US)

(72) Inventors: David Hobby, Wellington, CO (US); Zachary Gilvey, Johnstown, CO (US); Todd Bandhauer, Fort Collins, CO (US); John Cliff Denson, Birmingham, AL (US)

(73) Assignee: Impact Cooling Inc., Birmingham, AL (US)

(21) Appl. No.: 19/165,687

(22) PCT Filed: Mar. 21, 2024
(86) PCT No.: PCT/US2024/020903

§ 371 Date: Sep. 16, 2025

Related U.S. Application Data
(60) Provisional application No. 63/491,333, filed on Mar. 21, 2023.

(51) Int. Cl. H10W 40/47

(52) U.S. Cl. CPC H10W 40/475

(57) ABSTRACT

Impingement cooling devices include distributor plates having a plurality of injection ports and impingement target plates including a plurality of extraction ports. The plurality of injection ports accelerate a cooling fluid. The impingement target plate is arranged adjacent the distributor plate such that the accelerated cooling fluid is directed onto the impingement target plate and thereafter through the extraction ports. In some examples, an upstream side of the impingement target plate and/or at least one extraction port is provided with a plurality of protrusions configured to increase a conductive surface area of the upstream side of the impingement target plate and/or a conductive surface area within the at least one extraction port. In some examples, a first distributor plate is non-parallel with a second distributor plate and/or a first impingement target plate is non-parallel with a second impingement target plate.

### FIELD

The subject matter herein generally relates to jet impingement cooling devices, systems, and methods. More specifically, the subject matter herein relates to jet impingement cooling devices, systems, and methods for cooling electronic components on a printed circuit board.

### BACKGROUND

It is undesirable to allow an integrated circuit (IC) to run excessively hot, because excessive heating can lead to a reduced mean time between failures (MTBF) and reduced operating efficiency of the IC. Traditionally, the adverse effects of excessive heating of an electronic component such as an IC have been addressed by the use of a heat sink.

In one traditional solution, a heat sink includes a metal plate having a number of metal fins projecting upwards from the metal plate. The metal plate, which is affixed to a top surface of the IC by using a heat sink compound, conducts heat upwards from the IC and into the fins. Ambient air above the IC then dissipates the heat in the fins.

U.S. Pat. No. 10,533,809 discloses a cooling apparatus that includes a distributor plate and a conduit assembly. The conduit assembly allows a cooling fluid to flow downwards through a first set of holes in the distributor plate and onto a hot object placed below the distributor plate. The cooling fluid then flows upwards from the hot object into a second set of holes in the distributor plate. The first set of holes are shaped to offer a pressure increase to the cooling fluid flowing towards the hot object. The second set of holes are shaped to offer reduced resistance to the cooling fluid flowing away from the hot object. The distributor plate and the conduit assembly are fabricated from a material that is a heat insulator thereby preventing heat transfer from the cooling fluid flowing away from the hot object to the cooling fluid flowing towards the hot object.

International Application Publication No. WO 2021/155018 discloses an impingement cooling device including a distributor plate, a manifold, and a heat spreader. The distributor plate includes a first side, a second side opposite the first side, a plurality of injection ports extending through the distributor plate from the first side to the second side, and a plurality of extraction ports extending through the distributor plate from the first side to the second side. The manifold is coupled to the distributor plate and includes a partition wall separating the plurality of injection ports and the plurality of extraction ports on the first side. The heat spreader at least partially covers an object to be cooled and includes a top surface configured to oppose the second side of the distributor plate. The heat spreader further includes a surface feature on the top surface configured to increase heat transfer therefrom.

International Application Publication No. WO 2023/168324 discloses a jet impingement cooling system configured to cool high heat flux devices via a cooling fluid. The jet impingement cooling system may include a heatsink and a first supply surface. The heatsink is coupled to the high heat flux device or capable of being coupled to the high heat flux device. The heatsink includes a first impingement surface having exit orifices and impingement regions. The exit orifices are spaced-apart from each other and defined in the first impingement surface. The impingement regions are located between adjacent exit orifices. The first supply surface is spaced-apart from the first impingement surface and includes injection ports spaced-apart from each other and defined in the supply surface. The injection ports are oriented such that impingement jets therefrom are directed to impinge against the impingement regions.

The above patent and applications are hereby incorporated by reference herein.

### SUMMARY

The present disclosure is of a data center cooling system and method that modifies cooling in at least three levels. Air is routed from a location which is remote to the server (e.g., outside), filtered, introduced to the server rack, and routed to the heat generating components (e.g., chips) of individual servers; the heated air is then routed again to some remote location (e.g., outside) in an open-loop configuration. Through integration of a chip-level cooling subsystem, a server-level cooling subsystem, a rack-level cooling subsystem, and a facility-level cooling subsystem, the data center cooling system is controlled via a top-to-bottom feedback loop, a server-controlled feedback loop, or a combination of a server and facility-level feedback loop, which allows for efficient cooling when and where needed.

According to one example of the present disclosure, an impingement cooling device comprises a distributor plate including an upstream side, a downstream side opposite the upstream side, and a plurality of injection ports extending through the distributor plate from the upstream side to the downstream side. An impingement target plate includes an upstream side, a downstream side opposite the upstream side, and a plurality of extraction ports extending through the impingement target plate from the upstream side to the downstream side. The plurality of injection ports are configured to accelerate a cooling fluid as the cooling fluid passes therethrough from the upstream side to the downstream side of the distributor plate. The impingement target plate is arranged adjacent the distributor plate such that the accelerated cooling fluid is directed onto the upstream side of the impingement target plate and thereafter through the extraction ports to the downstream side of the impingement target plate. The upstream side of the impingement target plate and/or at least one extraction port in the plurality of extraction ports is provided with a plurality of protrusions configured to increase a conductive surface area of the upstream side of the impingement target plate and/or a conductive surface area within the at least one extraction port in the plurality of extraction ports, respectively.

According to another example of the present disclosure, an impingement cooling device comprises a first distributor plate including an upstream side, a downstream side opposite the upstream side, and a first plurality of injection ports extending through the first distributor plate from the upstream side to the downstream side and configured to accelerate a cooling fluid as the cooling fluid passes therethrough from the upstream side to the downstream side of the first distributor plate. A first impingement target plate includes an upstream side, a downstream side opposite the upstream side, and a first plurality of extraction ports extending through the first impingement target plate from the upstream side to the downstream side. A second distributor plate includes an upstream side, a downstream side opposite the upstream side, and a second plurality of injection ports extending through the second distributor plate from the upstream side to the downstream side and configured to accelerate the cooling fluid as the cooling fluid passes therethrough from the upstream side to the downstream side of the second distributor plate. A second impingement target plate includes an upstream side, a downstream side opposite the upstream side, and a second plurality of extraction ports extending through the second impingement target plate from the upstream side to the downstream side. The first impingement target plate is arranged adjacent the first distributor plate such that the accelerated cooling fluid is directed onto the upstream side of the first impingement target plate and thereafter through the first plurality of extraction ports to the downstream side of the first impingement target plate. The second impingement target plate is arranged adjacent the second distributor plate such that the accelerated cooling fluid is directed onto the upstream side of the second impingement target plate and thereafter through the second plurality of extraction ports to the downstream side of the second impingement target plate. The first distributor plate is non-parallel with the second distributor plate and/or the first impingement target plate is non-parallel with the second impingement target plate.

According to another example of the present disclosure, an impingement cooling device comprises a first plate including an upstream side, a downstream side opposite the upstream side, and a first plurality of ports extending through the first plate from the upstream side to the downstream side and configured to accelerate a cooling fluid as the cooling fluid passes therethrough from the upstream side to the downstream side of the first plate, and a second plate including an upstream side, a downstream side opposite the upstream side, and a second plurality of ports extending through the second plate from the upstream side to the downstream side and configured to accelerate the cooling fluid as the cooling fluid passes therethrough from the upstream side to the downstream side of the second plate. The first plate is arranged adjacent the second plate such that the accelerated cooling fluid from the first plurality of ports is directed onto the downstream side of the second plate and such that accelerated cooling fluid from the second plurality of ports is directed onto the downstream side of the first plate. The first plate is non-parallel with the second plate.

### BRIEF DESCRIPTION OF THE DRAWINGS

The accompanying drawings that are incorporated in and constitute a part of this specification illustrate several embodiments of the disclosure and, together with the description, serve to explain the principles of the disclosure. The present disclosure is described with reference to the following figures.

FIG. 1 is a schematic of a prior art closed loop cooling system.

FIG. 2 is a system overview of an airflow path through subsystems of an open loop cooling system in accordance with the present disclosure.

FIG. 3 is a top-level system diagram in accordance with the present disclosure.

FIG. 4 shows a prior art return jet impingement (RJI) cooling apparatus for use at a chip level of a cooling system.

FIG. 5 shows a cross-section taken along the line 5-5 in FIG. 4.

FIG. 6 is a plan view diagram of the prior art cooling apparatus of FIGS. 4 and 5.

FIG. 7 shows another prior art RJI cooling apparatus for use at a chip level of a cooling system.

FIG. 8 shows a close-up view of a portion of FIG. 7.

FIG. 9 shows another prior art RJI cooling apparatus, which utilizes area enhancement on a micro-scale.

FIG. 10 shows another prior art RJI cooling apparatus, which utilizes area enhancement on a jet-scale.

FIG. 11 shows another prior art RJI cooling apparatus, which utilizes area enhancement at a device level.

FIG. 12 shows another prior art RJI cooling apparatus, in which the impingement target surfaces are vertically oriented.

FIG. 13 shows a schematic of a prior art through jet impingement (TJI) cooling apparatus with extraction ports to allow fluid passage through vertically oriented impingement target surfaces.

FIG. 14 shows a perspective view of the TJI device of FIG. 13.

FIGS. 15-20 show prior art material reduction strategies from a side view for use on the vertically oriented impingement target surfaces of a device like that of FIGS. 13 and 14.

FIG. 21 shows a side view of two aligned extraction ports that extend through the vertically oriented impingement target surfaces of a device like that of FIGS. 13 and 14.

FIG. 22 shows a side view of two offset extraction ports that extend through the vertically oriented impingement target surfaces of a device like that of FIGS. 13 and 14.

FIG. 23 shows a pattern of superimposed extraction ports on two adjacent vertically oriented impingement target surfaces of a device like that of FIGS. 13 and 14.

FIG. 24 shows prior art injection port (jet) shapes including a conical jet, a drop jet, a square-to-circle jet, a tapered jet, a straight jet, and a non-linear jet.

FIG. 25 shows an exemplary chip-level cooling device in accordance with the present disclosure.

FIG. 26 shows a side view of the cooling device of FIG. 25 in accordance with the present disclosure.

FIG. 27 shows an example of port-scale (or jet-scale) area enhancement on an impingement target surface in accordance with the present disclosure.

FIG. 28 shows a detailed view of another example of port-scale area enhancement on an impingement target surface, which also includes micro-scale area enhancement, in accordance with the present disclosure.

FIG. 29 shows a plan view of an example of a chip-level cooling device with port-scale area enhancement and conductive material between target impingement surfaces.

FIG. 30 is a perspective view of a base plate for a chip-level cooling device in accordance with the present disclosure.

FIG. 31 shows a plan view of an example of a chip-level cooling device with area enhancement within a plurality of extraction ports, as well as lips provided on the outlets on the extraction ports.

FIG. 32 shows a plan view of an example of a chip-level cooling device with diverging impingement target plates.

FIG. 33 shows a plan view of another example of a chip-level cooling device with diverging impingement target plates, and also with converging distributor plates.

FIG. 34 is a perspective view of the inlet end of the device of FIG. 33.

FIG. 35 is a perspective view of an outlet end of the device of FIG. 33.

FIG. 36 shows a perspective view of the device of FIG. 33 with the cover plate intact.

FIG. 37 shows a side elevation view of the device of FIG. 33.

FIG. 38 is a plan view of the device of FIG. 33 with the distributor plates removed.

FIG. 39 is a perspective view of the device of FIG. 33 with the distributor plates removed and with some target impingement plates removed.

FIG. 40 is a close-up plan view of an alignment pin of the device of FIG. 33.

FIG. 41 shows a plan view of another example of a chip-level cooling device with diverging impingement target plates, and also with converging distributor plates.

FIG. 42 is a perspective view of the inlet end of the device of FIG. 41.

FIG. 43 is a perspective view of an outlet end of the device of FIG. 41.

FIG. 44 is another perspective view of the device of FIG. 41, with some of the distributor plates and impingement target plates removed.

FIG. 44A is a close-up plan view of alignment pins of the device of FIG. 41.

FIG. 45 shows a stock server.

FIG. 46 shows the stock server with a portion of a chip-level cooling device according to the present disclosure installed.

FIG. 47 shows the stock server with the cover manifold of the chip-level cooling device installed.

FIG. 48 shows the stock server with the chip-level cooling device and an intake manifold installed.

FIG. 49 shows a side perspective view looking into the intake manifold.

FIG. 50 shows an impingement target plate having a porous surface in accordance with the present disclosure.

FIG. 51 is a plan view of a device including multiple impingement target plates in accordance with the present disclosure.

FIG. 52 is a plan view of another device including multiple impingement target plates in accordance with the present disclosure.

FIG. 53 shows a device in which the impingement target surface is the surface of a plurality of cylinders.

FIG. 54 is a top-down schematic of two groups of impingement target cylinders.

FIG. 55 is a side elevation view of a device that utilizes a horizontally oriented impingement target plate.

FIG. 56 is a side elevation view of a device that utilizes stacked horizontally oriented impingement target plates.

FIG. 57 shows one possible arrangement for a server-level subsystem, with inlet and outlet flow consolidation in accordance with the present disclosure.

FIG. 58 shows a first manifolding method for a server-level subsystem in accordance with the present disclosure.

FIG. 59 shows a second manifolding method for a server-level subsystem in accordance with the present disclosure.

FIG. 60 shows a third manifolding method for a server-level subsystem in accordance with the present disclosure.

FIG. 61 shows a rack-level subsystem connected to server-level subsystems in accordance with the present disclosure.

FIG. 62 shows first examples of port covers in accordance with the present disclosure.

FIG. 63 shows second examples of port covers in accordance with the present disclosure.

FIG. 64 shows a redundant manifold and air delivery path in accordance with the present disclosure.

FIG. 65 shows facility-level airflow segregation in accordance with the present disclosure from a schematic standpoint.

FIG. 66 shows an exemplary implementation of facility-level airflow management in accordance with the present disclosure.

FIG. 67 shows a liner separation for hot and cold medias in accordance with the present disclosure.

FIG. 68 shows a system for the utilization of hot air recirculation for winter months in accordance with the present disclosure.

### DETAILED DESCRIPTION

In the following sections, detailed descriptions of examples and methods of the disclosure will be given. The description of both preferred and alternative examples, though thorough, are exemplary only, and it is understood to those skilled in the art that variations, modifications, and alterations may be apparent. It is therefore to be understood that the examples do not limit the broadness of the aspects of the underlying disclosure as defined by the claims.

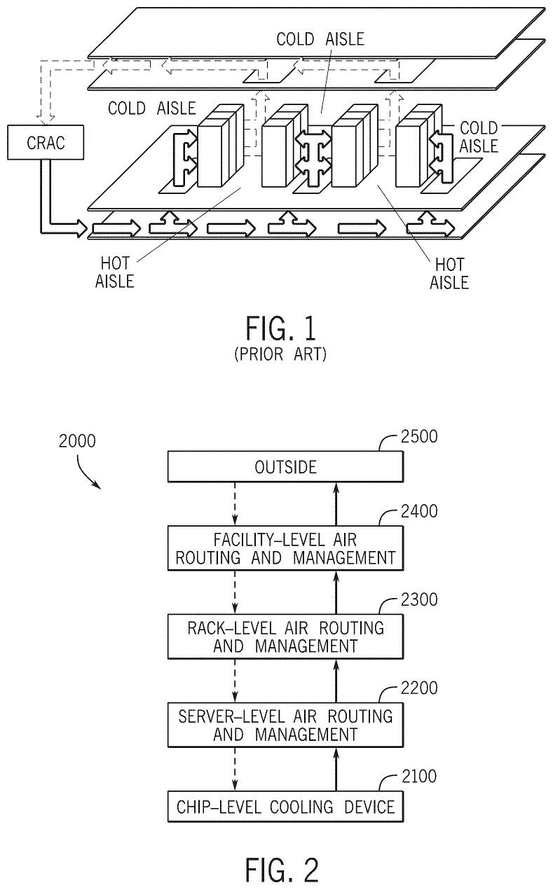

The technological boom has resulted in 3% of the world's electricity being used by data centers, where approximately 1% is used for cooling. A tremendous amount of heat is generated by servers to process, transport and store data. Typically, air is circulated in a closed loop cooling arrangement as shown in FIG. 1 to keep the servers within their operating temperature limits.

The present disclosure is of a data center cooling method that modifies cooling in three levels. Air is routed from a location which is remote to the server (e.g. outside), filtered, introduced to the server rack, and routed to the heat generating components of individual servers; the heated air is then routed again to some remote location (e.g. outside) in an open loop configuration as shown in FIG. 65. In one embodiment, the remote location could be outside the facility. In another embodiment, the remote location could be a cooling unit (e.g. A/C evaporator coil, liquid cooling coil) which removes heat from the air and transports that heat to a secondary location (e.g., a cooling tower, chiller, economizer, condenser, or other similar cooling unit which may be placed outside of the facility). This can eliminate some or all of the AC components. Subsystems will be introduced and the innovations around each will be described. A new type of impingement cooling device 2100 is also described which attaches on the server to cool the heat generating devices.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

Unless otherwise specified or limited, the phrases “at least one of A, B, and C,” “one or more of A, B, and C,” and the like, are meant to indicate A, or B, or C, or any combination of A, B, and/or C, including combinations with multiple instances of A, B, and/or C. Likewise, unless otherwise specified or limited, the terms “mounted,” “connected,” “linked,” “supported,” and “coupled” and variations thereof are used broadly and encompass both direct and indirect mountings, connections, supports, and couplings.

As used herein, unless otherwise limited or defined, discussion of particular directions is provided by example only, with regard to particular embodiments or relevant illustrations. For example, discussion of “top,” “bottom,” “front,” “back,” “left,” “right,” “lateral” or “longitudinal” features is generally intended as a description only of the orientation of such features relative to a reference frame of a particular example or illustration. Correspondingly, for example, a “top” feature may sometimes be disposed below a “bottom” feature (and so on), in some arrangements or embodiments. Additionally, use of the words “first,” “second”, “third,” etc. is not intended to connote priority or importance, but merely to distinguish one of several similar elements from another.

Note that, as used herein, the terms “jet” and “injection port” may be used interchangeably to refer to a nozzle-like port formed through a plate, which may be a distributor plate or a dual-function impingement target plate and distributor plate. The term “jet” may also be used as a verb and/or to describe the cooling fluid as it passes through the injection port of a distributor plate or a dual-function impingement target plate and distributor plate.

The term “fin” may be used interchangeably with the terms “impingement target surface” or “impingement target plate” to refer to a plate onto which fluid is jetted. In some cases, fluid may be jetted onto a fin or plate that initially provides an impingement target surface, but which also then acts as a distributor plate.

The term “fluid” may refer to a liquid, a gas, or a two-phase fluid (that is, a combination of a liquid and a gas). At times, the term “fluid” and the term “air” are used interchangeably.

The terms “impingement cooling device”, “chip-level cooling device”, “chip-level impingement cooling device”, and “chip-level subsystem” may also be used interchangeably herein.

### 1. Subsystem Introduction

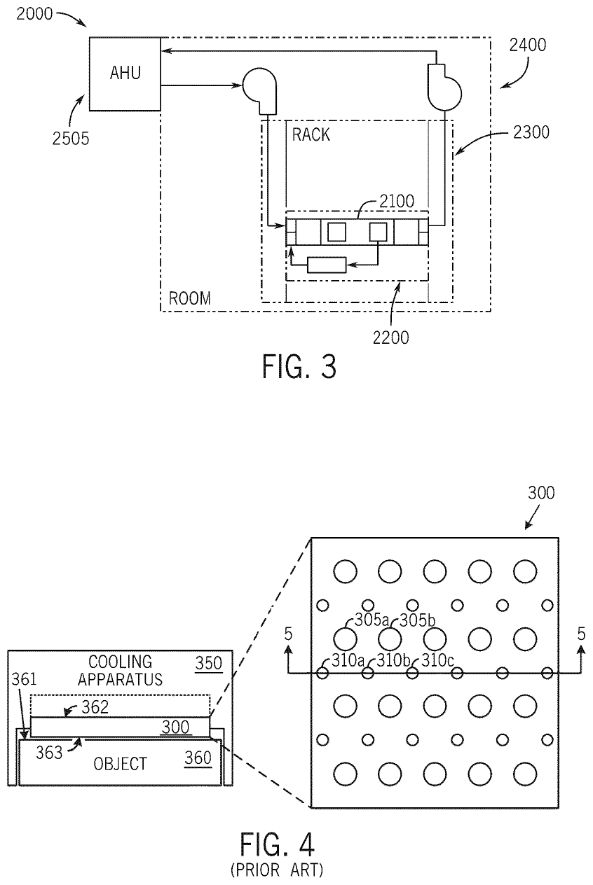

Referring to FIGS. 2 and 3, according to the present disclosure, there are four sub-systems which connect to provide cooling to the servers in the data center. Innovations around each of these subsystems will be discussed. The chip-level cooling device 2100 extracts heat directly from a heat-producing object (e.g., microchip) while the facility-level, rack-level, and server-level subsystems 2200, 2300, 2400 all serve to facilitate delivery of air to and from each chip-level cooling device 2100. The heat-producing object can alternatively be any of various types of objects, such as an integrated circuit that produces heat when in operation, a component that produces heat when conducting electrical current, or a module containing one or more components that produce heat when conducting electrical current. A few examples of ICs that produce heat when in operation include programmable ICs (field programmable gate arrays (FPGAs), programmable logic devices (EPLDs), application specific integrated circuits (ASICs), etc.) and non-programmable ICs. A few specific examples of ICs include central processing units (CPUs) and graphics processing units (GPUs). A few examples of components that produce heat when conducting electrical current include transistors, resistors, transformers, dynamic random access memory (DRAM), hard drives, and light emitting components (laser diodes, light emitting diodes, etc.). A few examples of modules containing one or more components that produce heat when conducting electrical current include a linear power supply module, a switching power supply module, and a laser module (transmitter, receiver, or transceiver).

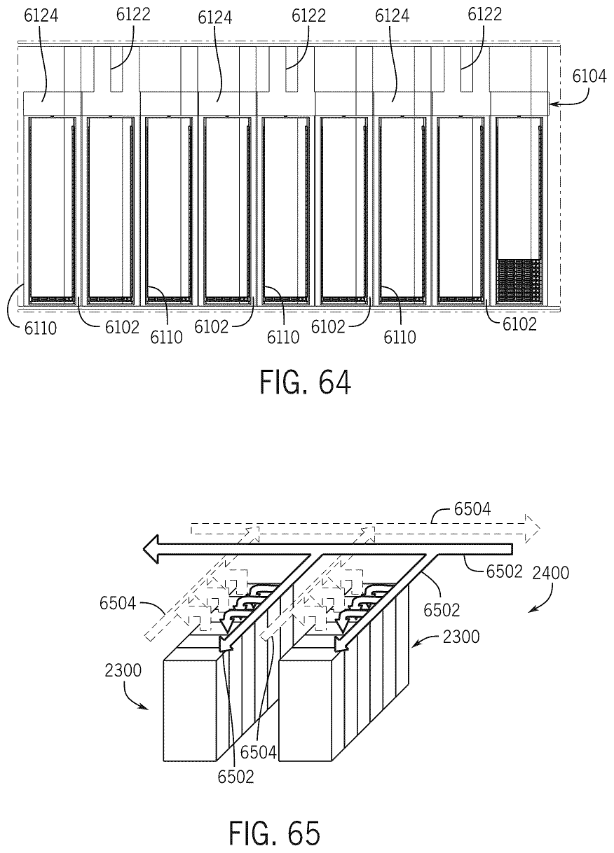

The facility-level subsystem 2400 (FIGS. 64-67) facilitates airflow management between each rack-level subsystem 2300 and some remote location (e.g., outside 2500 or a remote heat exchanger/cooling coil/radiator).

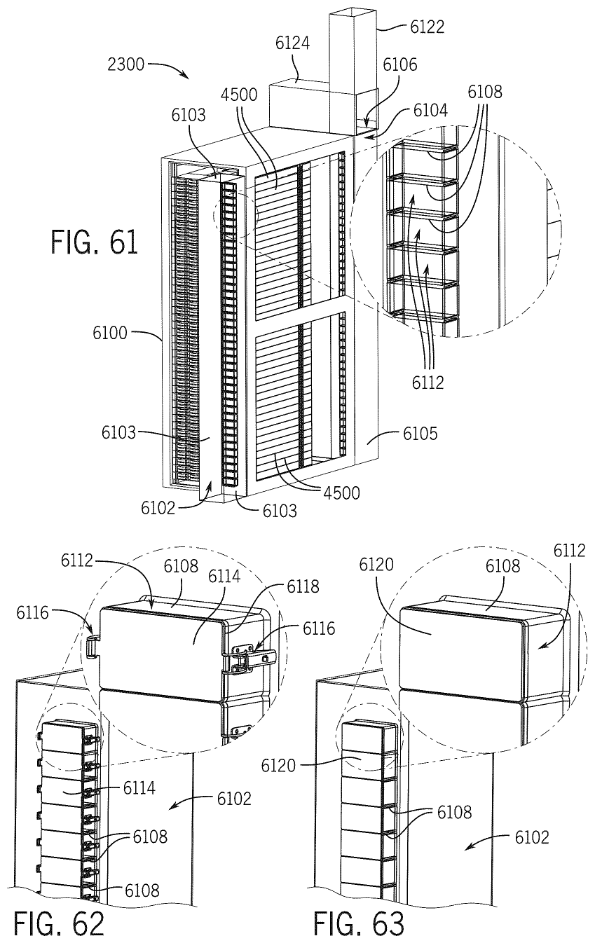

The rack-level subsystem 2300 (FIGS. 61-63) facilitates airflow management between each server-level subsystem 2200 and the facility-level subsystem 2400, which is optionally directly coupled with a remote or adjacent heat exchanger. The rack-level subsystem 2300 controls and delivers airflow to and from each server-level subsystem 2200 within the rack and can serve as a repeating unit cell within a data center facility.

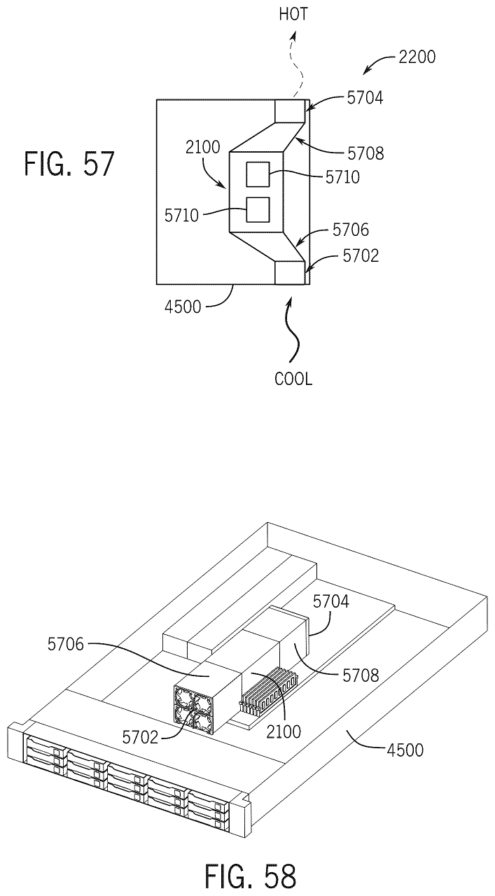

The server-level subsystem 2200 (FIGS. 57-60) facilitates airflow management within the boundaries of the server. This subsystem controls and delivers airflow from outside of the server boundary to each chip-level subsystem 2100 on the server. The server-level subsystem 2200 further controls and delivers exhaust airflow from each chip-level impingement cooling device 2100 outside of the server boundary and can serve as a single repeating unit cell within a rack of server equipment, coupled to the rack-level subsystem 2300.

The schematic of FIG. 2 provides a simple description of the airflow path through each subsystem of a cooling system 2000, while FIG. 3 is a top-level system diagram providing a simple overview of the system, including all subsystems. The innovations of these four subsystems will be described in the following sections. The “outside” 2500 condition could be any cooling source such as an air reservoir (e.g., another room) remote to each of the rack level subsystems; however, there are distinct advantages to having that cooling source be an ambient air source such as the outside air (provided to the facility-level subsystem 2400 via an air handling unit 2505, for example), as will be described herein below.

### 2. Chip-Level Cooling Device

Cooling device(s) are attached to components (e.g., microchip packages) on a larger electronic device (e.g., server). Some cooling fluid (e.g. air, water, hydrofluoroether, FC-series dielectric fluid) passes through the chip-level impingement cooling device 2100, extracting heat from the package and carrying it elsewhere for removal. The presently disclosed chip-level impingement cooling device 2100 serves as a direct replacement for conventional, state-of-the-art chip-level cooling devices used in, for example, servers or PCs that are cooled by air, liquid, or a two-phase fluid. The presently disclosed server-level and rack-level innovations are not strictly limited to use with the presently disclosed chip-level impingement cooling device 2100, but rather could optionally be implemented with other state-of-the-art chip cooling devices.

### 2.1. Return-Jet Impingement (RJI) Cooling Device

An RJI (return jet impingement(device presents one option for a chip-level impingement cooling device to be integrated into the larger system.

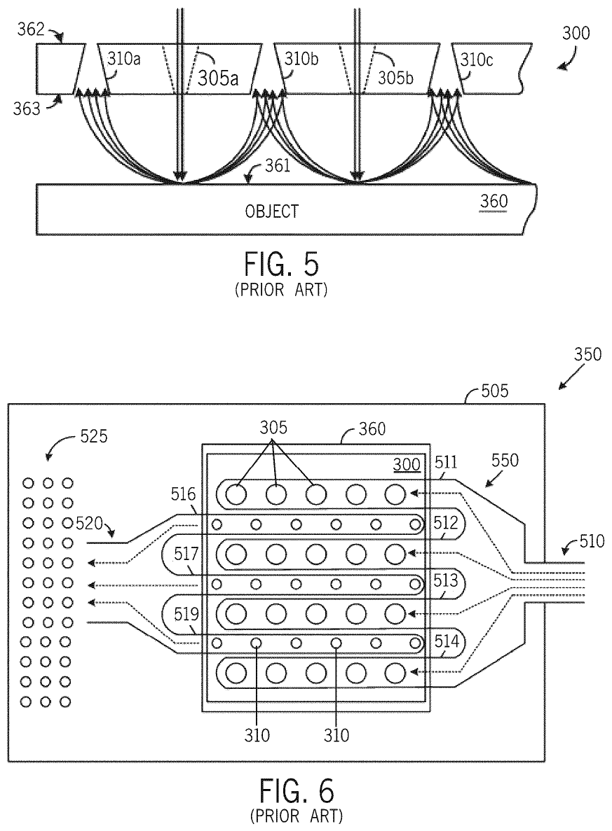

Referring to FIG. 4, an RJI cooling apparatus 350 incorporates a distributor plate 300 including an array of injection ports 305a, 305b with a secondary array of interspersed extraction ports 310a, 310b, 310c to avoid performance degradation caused by interactions between injection ports. The ports extend through the distributor plate 300 from a first major surface 362 to a second major surface 363. In this illustration, the first major surface 362 corresponds to a top surface of the distributor plate 300 and the second major surface 363 corresponds to a bottom surface of the distributor plate 300. The cooling apparatus 350 is placed over an object 360 such that the bottom surface of the distributor plate 300 faces a hot target surface 361 of the object 360. Details of the flow path are shown in FIG. 5, which is a cross-section taken through the distributor plate 300 of FIG. 4, where the arrows represent the flow path of the fluid. Cooling fluid moves through the conical injection ports 305a, 305b to impact the target surface 361, turn laterally and return up the adjacent extraction ports 310a, 310b, 310c. In FIG. 6, the flow path is shown for the device of FIG. 4. Fluid enters via the inlet port 510, which is split into a plethora of channels 511, 512, 513, 514, which further distribute the fluid to the injection ports 305. Fluids contacts the target surface 361 of the object 360 and thereafter moves via the extraction ports 310 into channels 516, 517, 518. Channels 516, 517, 518 converge into outlet port 520. The cooling apparatus 350 includes a housing 505, and the hot fluid emerging from the outlet port 520 of the housing 505 is vented out of the housing 505 through a set of vents 525. Further details of such a device may be found in U.S. Pat. No. 10,533,809, incorporated by reference herein.

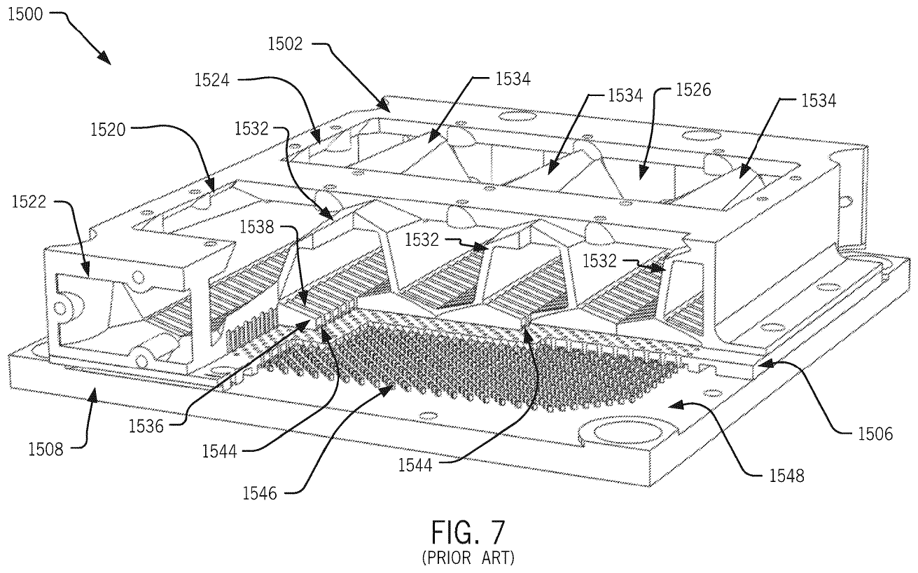

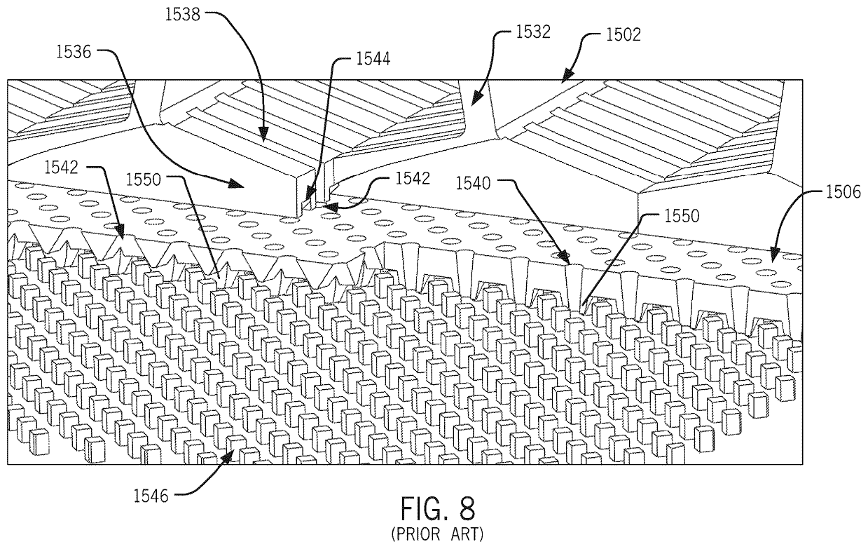

Further developments of the RJI design, disclosed in International Application Publication No. WO 2021/155018, incorporate area enhancement on the target surface 361, drop jets, nonlinear jets, and manifold innovations. In FIGS. 7 and 8, the impingement cooling device 1500 is split between three main components: (1) the target surface 1548, on base plate 1508, which is made of copper and contains area enhancement using extruded fins 1546 such as pin fins; (2) the distributor plate 1506, which contains drop jets 1540 and extraction ports 1542; and (3) the manifold 1502. In one embodiment, the distributor plate 1506 and manifold 1502 are one solid component. As shown in FIG. 8, material 1550 surrounding the drop jets 1540 extends below the plane of the distributor plate, allowing the jets 1540 to be closer to the target surface 1548, where the extruded fins 1546 would otherwise interfere. Cooling fluid enters from a top opening 1520 and a front opening 1522 into inflow enclosures 1534, each of which has a converging trapezoidal shape, initially starting with a large cross-sectional area and converging to a smaller cross-sectional area. The fluid is routed from the inflow enclosures 1534 to channels 1544, which distribute the fluid to the drop jets 1540. Fluid contacts the target surface 1548 then flows through the extraction ports 1542, through channels 1538 defined by vertically oriented walls 1536, into outflow enclosures 1532. The outflow enclosures 1532 each start with a small cross-sectional area and diverge to a larger cross-sectional area. This improves flow uniformity and pressure drop. Fluid then exits the manifold 1502 via the top opening 1524 and the side opening 1526.

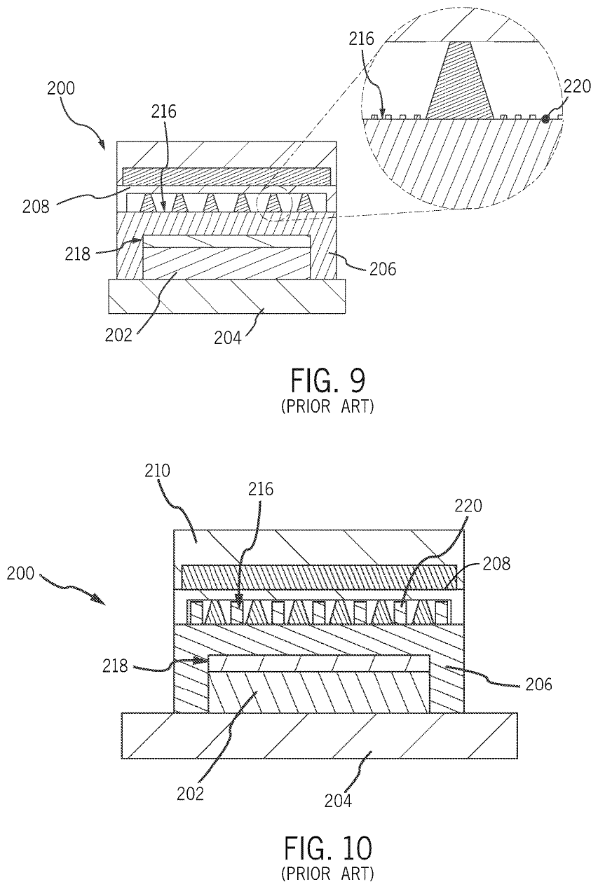

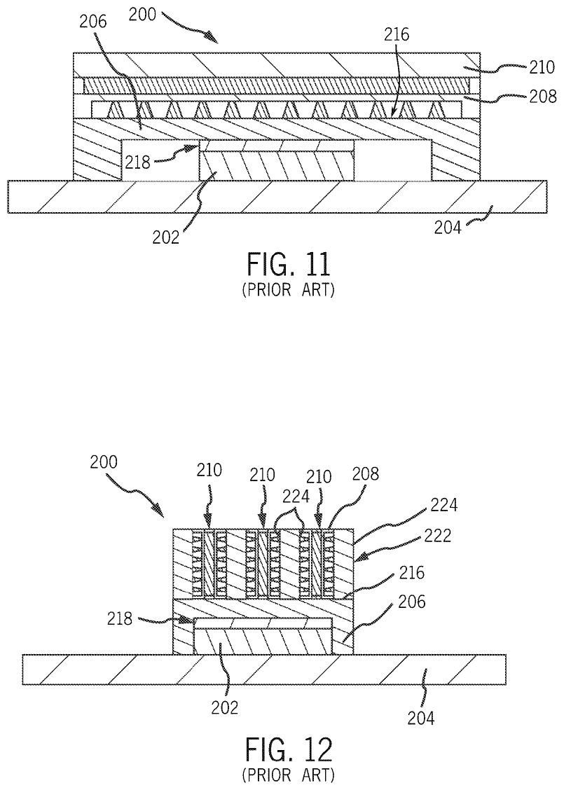

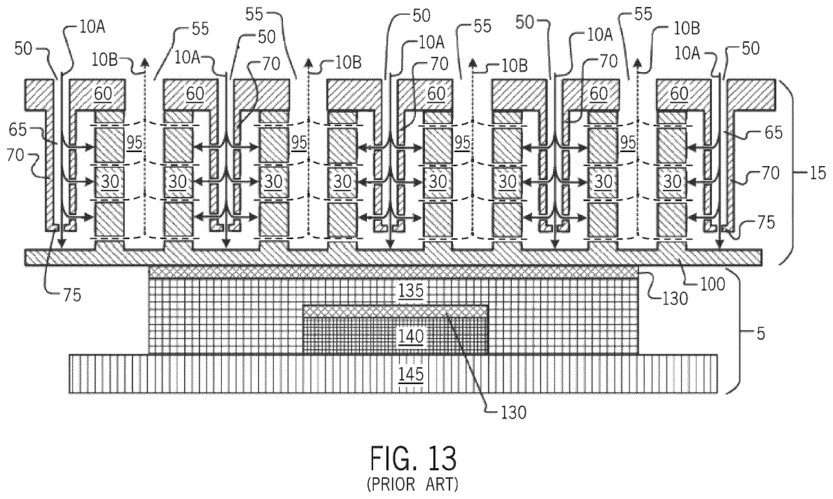

Options for area enhancement similar to that provided by fins 1546 are shown on three scales in FIGS. 9-11. These figures show a jet impingement cooling device 200, a heat-spreading lid 206, and an object 202 to be cooled. The object 202 (e.g., an integrated circuit) is shown mounted to a board 204, such as a printed circuit board (PCB). The lid 206 is thermally bonded to the object 202 via a thermal interface material (TIM) 218. The jet impingement cooling device 200 includes a distributor plate 208 positioned adjacent the top of the lid 206 and a manifold 210, which is positioned on top of the distributor plate 208. The distributor plate 208 includes injection and extraction ports for the cooling fluid to flow there through, and the manifold 210 directs fluid flow to the inlet port and from the exit port. Micro-scale area enhancement (FIG. 9) uses small (micro-scale) surface features 220 relative to the jet size. Jet-scale area enhancement is similar to the jet size, as shown with the extruded fins 220 in FIG. 10. Package scale area enhancement (FIG. 11) is where the target surface 216 has a larger cross-sectional area, spreading laterally, with respect to the object 202. All of these area enhancement techniques may be used simultaneously. In FIG. 12, vertical fins 222 have vertical faces 224 that are jetted on, which arrangement can also have the noted three area enhancements.

### 2.2. Through-Jet Impingement (TJI) Cooling Device

A TJI (through-jet impingement) device presents another option for chip-level cooling to be integrated into the larger system. Similar to the return jet impingement technology, TJI technology couples an impingement cooling device to an object to be cooled. Both RJI and TJI include an array of injection ports with an interspersed array of extraction ports. The two technologies are primarily differentiated by the direction of fluid extraction. In contrast to the RJI design, TJI incorporates flow extraction ports into the impingement target rather than into the impingement cooling device's distributor plate.

### 2.2.1. TJI Prior Art

A TJI device described in International Application Publication No. WO 2023/168324 is shown in FIG. 13. Cooling supply channels 65 provide inlet fluid 10A, which impinges on vertical fins 30 with material removed so the fluid can pass through the fin 30 after impinging upon it. The cooling supply channels 65 (defined by sidewalls 70 and bottom walls 75) and pairs of heatsink fins 30 are in an alternating arrangement across the jet impingement assembly 15, with each pair of heatsink fins 30 located between a pair of cooling supply channels 65, or vice versa. As shown, cylindrical through-holes have been created in the fins 30. The jet impacts the surface of the fin 30, turns laterally and then axially and moves through the outlet channels 95 between adjacent fins 30, as outlet fluid 10B. The separate supply channels 65 and outlet channels 95 avoid jet-jet interaction. The jet impingement assembly 15 is operably coupled with a high heat flux device 5 in a way to maximize heat transfer from the high heat flux device 5 to the cooling fluid 10 routed through the jet impingement assembly 15. As illustrated, this coupling may involve a layer of thermal interface material (TIM) 130 (e.g., thermal grease, hard or soft solder, graphite pad, indium pad, liquid metal, etc.) interposed between the bottom of the heatsink plate 100 and a top of the high heat flux device 5, the top of which may be a heat spreader lid 135. Another layer of TIM 130 may be found between the bottom of the heat spreader lid 135 and a top of an integrated circuit 140, which may be supported on top of a printed circuit board (PCB) 145, thereby rounding out the components of an example high heat flux device 5.

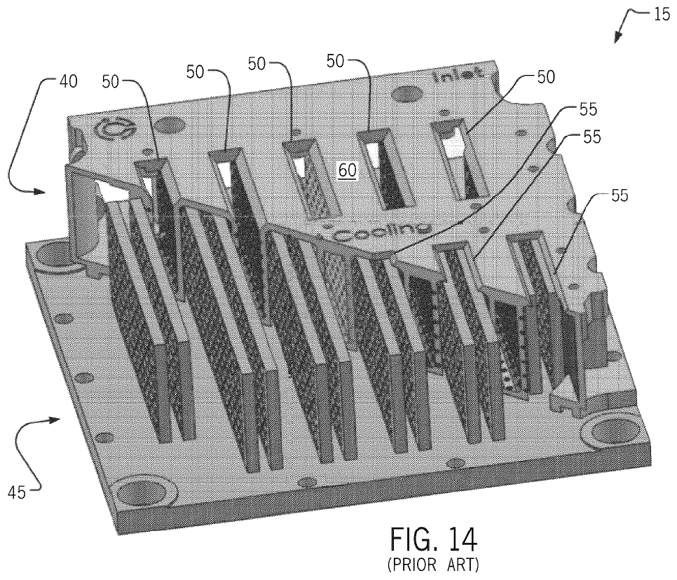

An TJI assembly 15 is shown in FIG. 14. Fluid enters the manifold 40 (which is shown as being partially cut away) via inlets 50 formed in a top plate 60 and from there is routed to the cooling supply channels 65 of FIG. 13. Fluid is jetted onto the vertical faces of the fins 30 and the upper face of the bottom plate 45, then passes through the fins 30 into the outlet channels 95, after which it is directed out of the manifold 40 via the outlets 55. This results in high heat transfer rates, stripping the heat away from the heat producing device. When compared to RJI, TJI requires drastically lower pressure drop and increases heat transfer area.

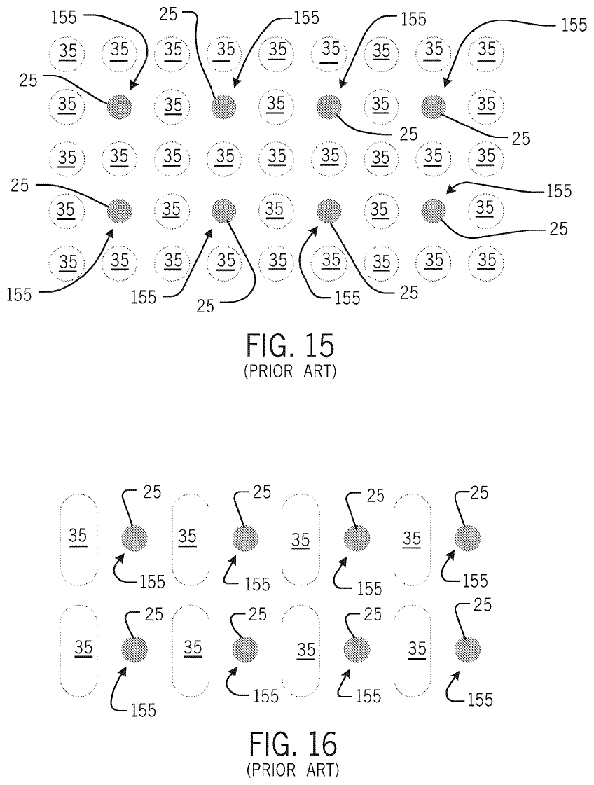

The vertical fins 30 may contain a number of material removal strategies to allow fluid to move through the fin 30. In FIGS. 15-20, a number of material removal strategies are shown on the fin to act as extraction ports 35. The material removal of FIG. 15 is also shown on the real base plate in FIG. 14. The jets in this pattern impact the target surface 155 where shown at 25, turn laterally and move axially through the eight surrounding extraction ports 35. In another example, the jetted fluid moves through four or six surrounding extraction ports. In FIG. 16, the jets impact the target surface 155 at 25 and moves through elliptical shaped extraction ports 35. In other examples, the extraction ports 35 could be conical shapes, which could be drafted in either direction (up or down).

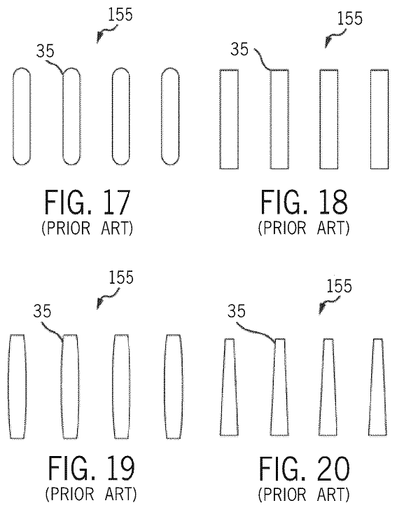

FIGS. 17-20 show more material reduction methods. In FIG. 17, elliptical shapes have been cut out of the fin 30. The fluid impacts the target surface 155, turns laterally and then axially and moves through these elliptical shaped extraction ports 35. In FIG. 18, rectangular channels have been cut out of the fin 30. The fluid jets onto the target surface 155 and moves through these rectangular extraction ports 35, which further define the flow path of the cooling fluid. In FIG. 19, a conical rectangular pattern has been cut out with a draft that could be pointed in either direction. For example, the cutout starts larger at the entrance and then converges, or the cutout starts smaller at the entrance and then diverges. The fluid impacts the target surface 155 and moves through these conical rectangular extraction ports 35. The draft allows each extraction port 35 to act as a converging-diverging nozzle and accelerate the fluid towards the next surface. The draft may also be advantageous for manufacturing reasons (e.g., when casting). In FIG. 20, inverted trapezoids have been cut out of the fin 30. The fluid impacts the target surface 155 and moves through these inverted trapezoidal extraction ports 35. The trapezoidal shape improves conduction heat transfer and fin efficiency. Any of these shapes may extend up to or through the top of the fin 30 and may contain any combination of the listed geometries. Further, any of these features may contain a draft to mix the fluid boundary layer or for ease of manufacturing.

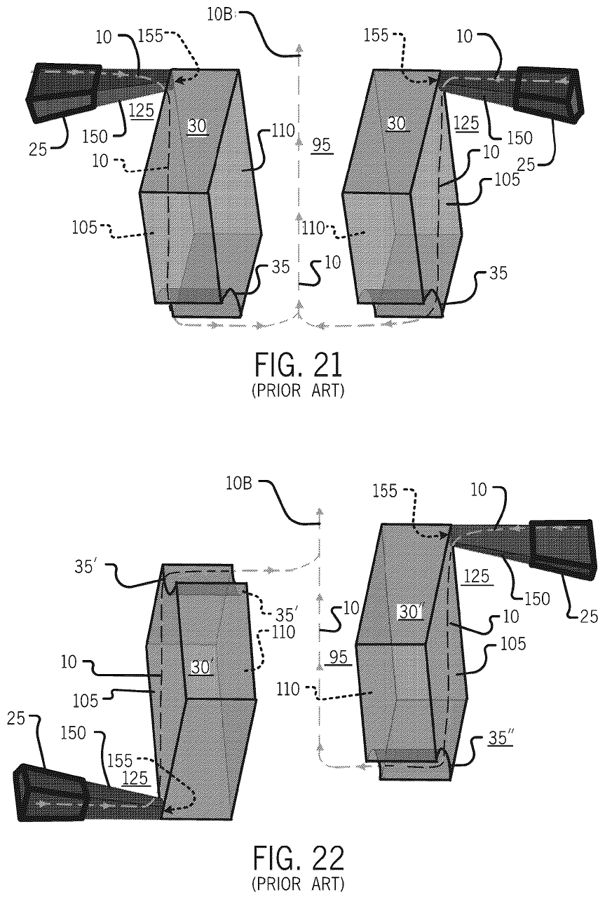

Each group of two fins 30 may be defined as a first fin and a second fin. If the extraction ports are aligned, after the fluid goes through the extraction ports 35, it would intersect as shown in FIG. 21. FIG. 21 is a diagrammatic depiction of fluid flow from the injection ports 25, across the heatsink fins 30, through the extraction ports 35 and out the hot outlet channel 95, where the injection ports 25 are offset from the extraction ports 35. Because the injection ports 25 are offset relative to the extraction ports 35, the high velocity fluid impingement jets 150 from the injection ports 25 impact the blank target surfaces 155 of the heatsink fin 30 between the extraction ports 35. After impacting the blank target surfaces 155, the cooling fluid 10 flows across the impact-side surfaces 105 of the heatsink fins 30 before exiting through the extraction ports 35. In passing along the impact-side surfaces 105 of the heatsink fins 30, the cooling fluid 10 absorbs heat from the heatsink fins 30 via convection and the temperature of the cooling fluid 10 increases.

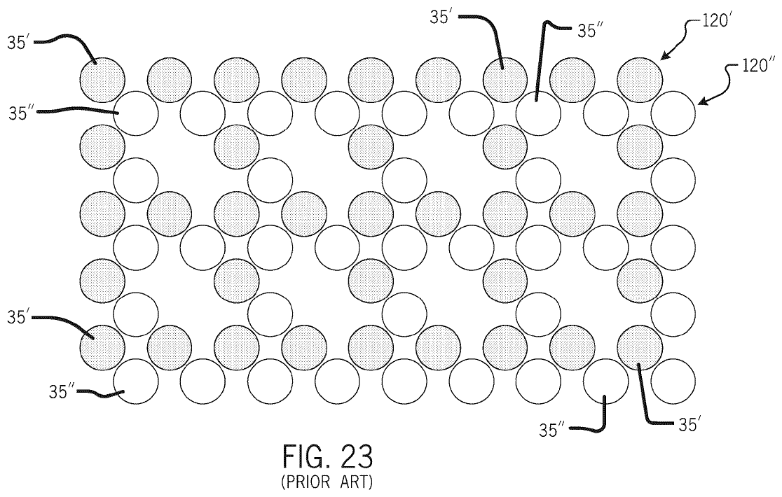

In another example, the patterns on the first fin and second fin may be offset from one another to avoid unwanted fluid interaction. A side view of exemplary offset patterns of extraction ports 35′ on the first fin 30′ and extraction ports 35″ on the second fin 30″ is shown in FIG. 23, while a detailed view of opposite extraction ports is shown in FIG. 22. FIG. 22 is a diagrammatic depiction of fluid flow across the heatsink fins 30′, 30″ where the injection ports 25 are offset from the exit orifices 35′, 35″ and the exit orifices 35′, 35″ of adjacent heatsink fins 30′, 30″ forming a common hot outlet channel 95 are also offset from each other. FIG. 23 is a pattern of a first exit orifice array 120′ of a first heatsink fin 30′ of FIG. 22 superimposed over a pattern of a second exit orifice array 120″ of a second heatsink fin 30″ of FIG. 22. Fluid flows from the injection ports 25, across the heatsink fins 30′, 30″, through the exit orifices 35′, 35″ and out the hot outlet channel 95. In doing so, it can be seen that not only are the injection ports 25 offset from the exit orifices 35′, 35″, but the exit orifices 35′, 35″ of adjacent heatsink fins 30′, 30″ forming a common hot outlet channel 95 are also offset from each other. By superimposing the arrays 120′, 120″ as shown in FIG. 23, it can readily be understood that the exit orifices 35′, 35″ respectively making up the arrays 120′, 120″ are offset from each other.

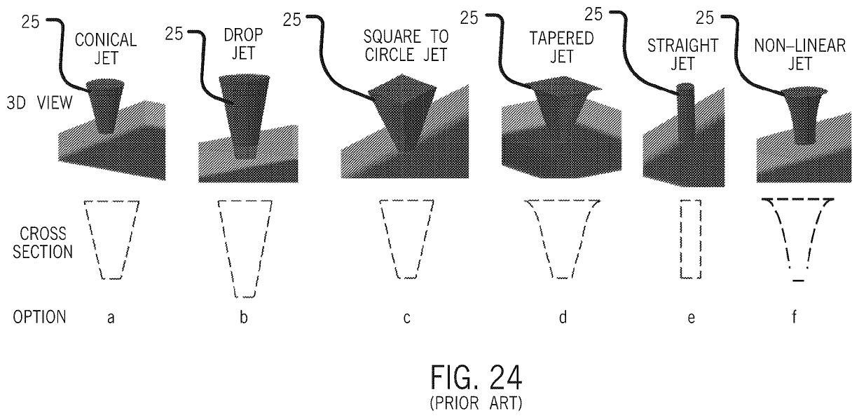

Innumerable jet shapes are also possible to accelerate the fluid to impact the target surface 155. Conical jet shapes are the most common as they are the best for reducing pressure drop. The negative of a jet shape inside the distributor plate (defined by walls 70, 75 in FIG. 13) is shown in FIG. 24, where the lower shaded region represents the volume in between the distributor plate and the target surface 155. Option a shows the most common jet shape, a conical jet. In option b, the conical jet has been extended below the distributor plate, forming what is referred to herein as a “drop jet.” This conical jet doesn't need to come from another circle, it may also come from a larger cross-sectional area such as a square (option c). This larger cross-sectional area may be further expanded by adding a transition region, such as a fillet or chamfer around the entrance of the jet 36 (option d). Straight jets without conical shapes are also contemplated, as shown by option e, although they may perform less well due to more pressure drop. Finally, non-linear jet 38 shapes that transition from a larger cross-sectional area to the jet diameter are shown in option f. This would result in the lowest pressure drop while attaining the desired jet velocity. These various injection port designs may provide a variety of desirable performance characteristics, may be useful to achieve specific velocity, and may be more suitable to specific manufacturing techniques.

### 2.2.2. TJI New and Innovative

### 2.2.2.1. TJI Device with Hierarchical Cooling Features

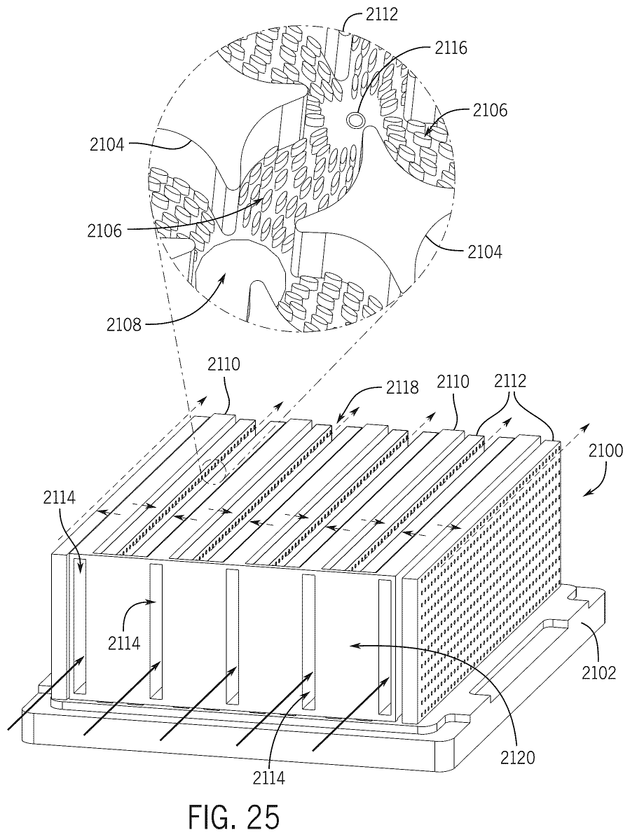

Here, an overview of the new and inventive embodiments of TJI cooling devices are provided. This shall help to identify innovations which are not specifically pointed out in the sections below. Here (FIG. 25) an impingement cooling device 2100 is integrated directly onto the lid (which acts as the baseplate 2102) of a CPU, GPU, ASIC, FPGA or relevant IC (integrated circuit). The impingement cooling device 2100 includes a plurality of distributor plates 2110 interspersed with a plurality of impingement target plates 2112, which extend perpendicularly with respect to the base plate 2102. The flow of the cooling fluid is shown by the arrows. Inlet cooling fluid is provided to inlet channels 2114 defined between the distributor plates 2110 and turns laterally through injection ports (not shown). Each injection port accelerates the fluid into a jet, which initially contacts the impingement target plate 2112 at the exemplary area shown at 2116, after which the fluid flows through extraction ports 2108. After flowing through extraction ports 2108, the fluid again turns and flows through outlet channels 2118 defined between adjacent impingement target plates 2112. The ends of the inlet channels 2214 and outlet channels 2118 are closed by end caps, one of which is shown at 2120. A manifold (not shown) is provided over the assembly shown in FIG. 25 to close off the top and sides of the device and to provide inlet and outlet ports for the flow of cooling fluid.

As shown in the detailed view, the impingement cooling device 2100 incorporates significant area enhancement on the impingement target plates 2112 using port-scale protrusions 2104 and micro-scale protrusions 2106, both of which will be described further herein below. The area enhancements in the device of FIG. 25 help direct the fluid to the extraction ports 2108 while providing significant heat transfer improvements. As described herein below, the height of the micro-scale protrusions 2106 may gradually increase towards the extraction port 2108, growing at a similar rate to the fluid boundary layer.

### 2.2.2.2. Mating and Alignment

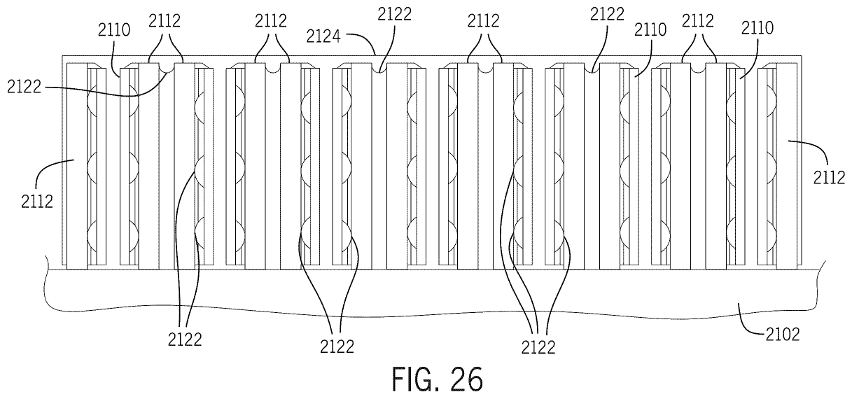

The mating between the base plate 2102 and the distributor plates 2110 and/or manifold 2124 (see FIG. 26) can be accomplished via several methods for ease of installation, reliability, or jet alignment. The manifold 2124 (into which the distributor plates 2110 may be integrated) can be clipped onto the base plate 2102 for ease of installation and replacement (see FIG. 37). In one embodiment, this replacement can take place while the server is running (hot swap). In one embodiment, the manifold 2124 is clipped onto the base plate 2102 like a cartridge, which allows for toolless installation. The manifold 2124 can be fastened to the base plate 2102 with fasteners to securely mount the impingement cooling device 2100. With reference to FIG. 26, several alignment features are also possible, including ribbed guide vanes 2122 on the manifold 2124, the distributor plates 2110, and/or the base plate 2102. The ribbed guide vanes 2122 may help align the distributor plates 2110 and manifold 2124 within the channels defined between adjacent impingement target plates 2112, and/or similar alignment features may be used to prevent the impingement target plates 2112 from moving. Drop jets (e.g., FIGS. 8, 24) can also be implemented to place the jets closer to the base plate 2102 and/or impingement target plates 2112, and/or for alignment. In one embodiment, the drop jets may extend downward until they are actually touching the surface of the base plate 2102 and/or impingement target plates 2112. Slits or other features could be cut into the drop jet at the nozzle exit point to allow for flow to exit outward from the nozzle after impacting the surface of the base plate 2102 and/or impingement target plates 2112. In one embodiment, a gasket can optionally also be used to keep the fluid from escaping from the system. This embodiment might be useful by reducing alternative flow paths that could cause jet-to-jet interference.

### 2.2.2.3. Baseplate Area and Heat Transfer Enhancement

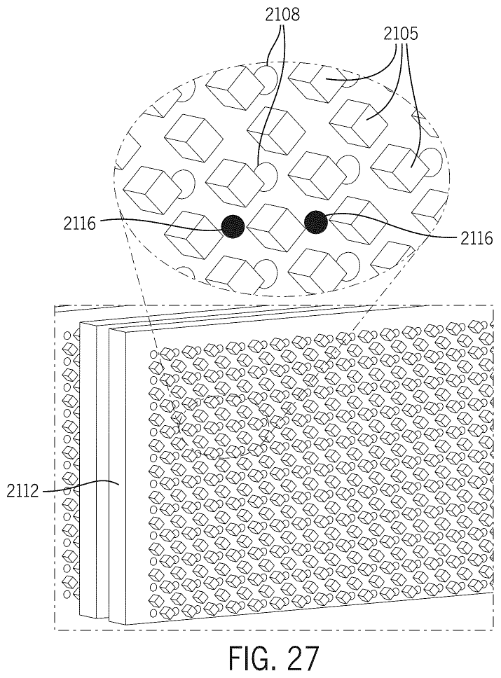

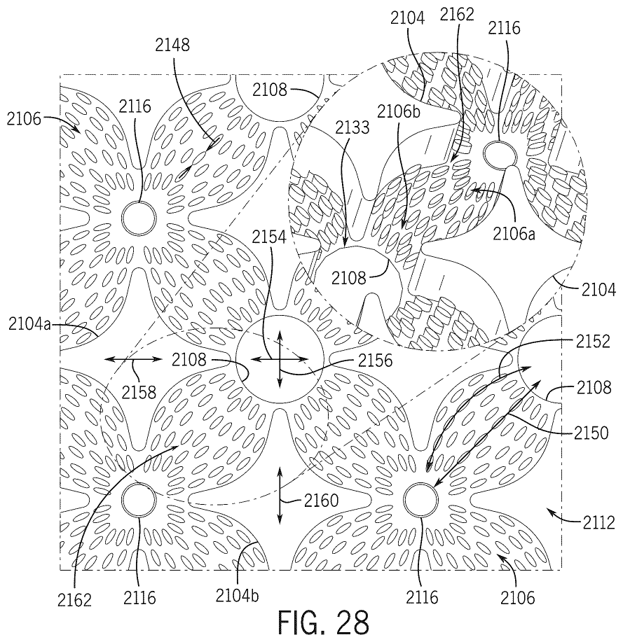

Recall with respect to FIG. 13 that TJI devices can accelerate fluid onto both vertical impingement target plates and the horizontal base plate. According to the present invention, the impingement target plates 2112 and/or base plate 2102 can include a number of features to improve surface area and thus heat transfer. Extruded protrusions such as pin fins for area enhancement can be added onto the impingement target surface (on impingement target plates 2112 and/or base plate 2102). An isometric view of one example of such protrusions 2105, which have port-scale dimensions similar to dimensions of the injection ports (not shown) and extraction ports 2108, is shown in FIG. 27. In one example, the port-scale protrusions have a cross-sectional dimension of 200-2000 microns. The accelerated fluid from a given injection port impacts the main plane of the impingement target plate 2112 at a central area 2116 between these protrusions 2105 (where impact area 2116 is directly opposite the given injection port), turns laterally, and is directed into the extraction ports 2108. The protrusions 2105 are illustrated as being square, but may instead be circular, elliptical, hydrofoil-shaped, or irregular shapes. The protrusions 2105 are shown as being perpendicular to the main plane of the impingement target plate 2112, but may instead be angled to various degrees (e.g., up to about 30 degrees) to ease manufacturing when made by 3D printing or other manufacturing methods.

Micro-scale area enhancement may also be added onto the impingement target plates 2112 and/or base plate 2102 with or without the larger port-scale protrusions. This micro-area enhancement may be square, circular, elliptical, hydrofoil-shaped or irregularly shaped. In one example, the micro-scale protrusions have a cross-sectional dimension of 0.1-200 microns. A section of an impingement target plate with both micro-scale protrusions 2106 and port-scale protrusions 2104 is shown in FIG. 28. Note that the port-scale protrusions 2104 are not square (as in FIG. 27), but instead have a curved diamond shape in cross section. The accelerated fluid exiting the injection ports impacts the center (at area 2116) of irregular star-shaped (or flower-shaped) areas defined between the port-scale protrusions 2104, which direct fluid to the extraction ports 2108. While the fluid is moving laterally to the extraction ports 2108, additional heat transfer is accomplished by the micro-scale protrusions 2106. In one arrangement, the micro-scale protrusions 2106 may be variable in height, in which the micro-scale protrusions 2106 closest to the area 2116 where the jet first impacts the target surface are shorter than the micro-scale protrusions 2106 furthest from the area 2116 (i.e., closest to the extraction ports 2108). This is seen in FIG. 28, where micro-scale protrusions 2106a are the shortest and micro-scale protrusions 2106b are the tallest. This progressive change in height may follow the fluid boundary layer, resulting in maximum heat transfer.

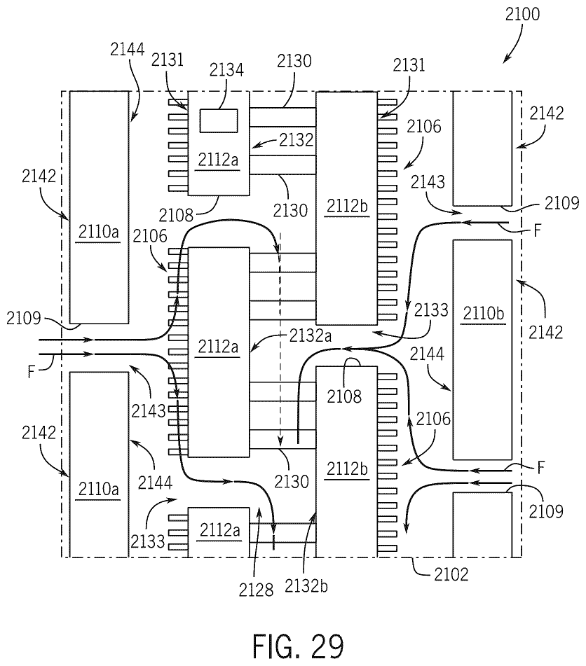

The top-down view of an exemplary flow path through the impingement cooling device 2100 may be seen in FIG. 29 with additional features that will be discussed next. Two opposed distributor plates 2110a, 2110b have injection ports 2109 that accelerate fluid F onto a first impingement target plate 2112a and a second impingement target plate 2112b, respectively. The micro-scale protrusions 2106 are shown on the impingement target plates 2112a, 2112b. Accelerated fluid impacts the impingement target plates 2112a, 2112b, turns laterally and then axially and moves through extraction ports 2108 before exiting in a common outlet channel 2128 as shown by the arrows.

### 2.2.2.4. Baseplate Conduction Enhancement

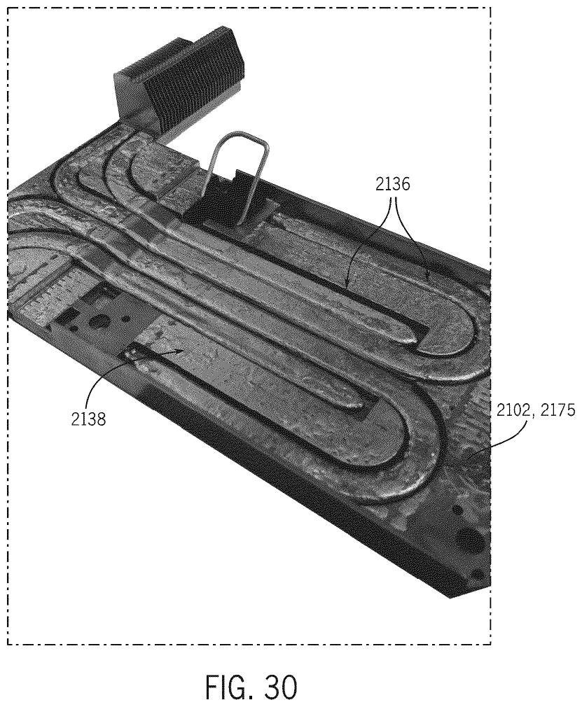

The impingement target plates 2112 can contain further features to improve conduction and heat transfer. In one embodiment, as shown in FIG. 29, conductive material 2130 spans the outlet channel 2128 between the downstream side 2132a of the first impingement target plate 2112a and the downstream side 2132b of the second impingement target plate 2112b. This conductive connection between the two impingement target plates 2112a, 2112b may be in the form of cylindrical posts as shown here, or may be in the form of rectangular fins, louver fins, metallic foam and/or spun-like web material connecting to the baseplate 2102 and/or the impingement target plates 2112. The conductive posts may be horizontal or angled upwards. When angling the posts upward, the posts may be larger in cross sectional area at the lower side (closer to the baseplate 2102) and may converge in cross sectional area moving up the post. In some embodiments, supports may be attached to the webbed features. In another embodiment, a vapor chamber 2134 may be formed in one or more of the impingement target plates 2112a, which may improve conduction and heat spreading. In another embodiment, heat pipes may also be routed and thermally bonded to the impingement target plates 2112. A vapor chamber or heat pipe may also be bonded to or otherwise integrated into the base plate to improve conduction and heat spreading. For example, FIG. 30 shows channels serving as heat pipes 2136 formed in the upper surface 2138 of a support plate 2175 that is to be placed on top of the object to be cooled. The baseplate 2102 of FIG. 25 may be attached over the support plate 2175. Alternatively, the support plate 2175 may be one and the same as the baseplate 2102 of FIG. 25, in which case the heat pipes may be formed in the lower surface of the combined support plate/baseplate.

The impingement target plates 2112 of the impingement cooling device 2100 may be other shapes besides rectangular. As an example, the impingement target plates may be trapezoidal, where the accelerated cooling fluid impacts a target surface that is 1 to 10 degrees angled relative to the surface of the baseplate 2102. As the impingement target plate has a larger thickness at the base and converges to a smaller thickness at the tip, this improves conduction efficiency via the thicker impingement target plate, thus further improving heat transfer.

### 2.2.2.5. Through Hole Area Enhancement

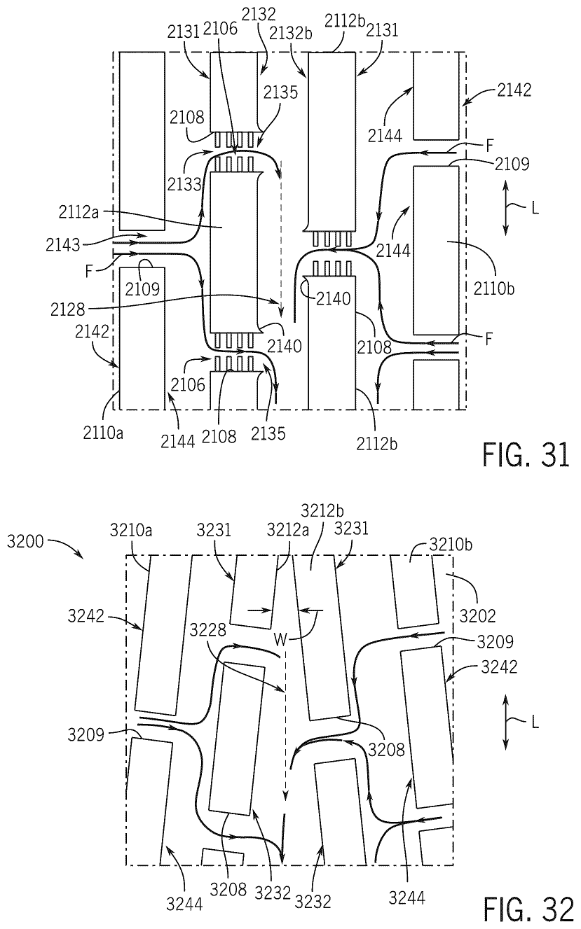

Referring to FIG. 31, area enhancement may also be added inside of the extraction ports 2108 that extend through the impingement target plates 2112. This area enhancement inside of the extraction ports 2108 may simply be grooves like a female thread or it may be protrusions 2106 that are, for example, 3D-printed inside the hole. Additionally or alternatively, area may be added at the entrance or exit of the extraction ports 2108, such as for example as a byproduct of a stamping process. For example, lips 2140 may be provided on the downstream side 2132b of an impingement target plate 2112b adjacent an outlet of at least one extraction port 2108. These lips 2140 add additional area and trip the exiting flow in the outlet channel 2128. Metallic foam (not shown) may also be provided in the extraction ports 2108.

With particular reference to FIG. 29, FIGS. 25-31 therefore provide an impingement cooling device 2100 comprising a distributor plate 2110 including an upstream side 2142, a downstream side 2144 opposite the upstream side 2142, and a plurality of injection ports 2109 extending through the distributor plate 2110 from the upstream side 2142 to the downstream side 2144. An impingement target plate 2112 includes an upstream side 2131, a downstream side 2132 opposite the upstream side 2131, and a plurality of extraction ports 2108 extending through the impingement target plate 2112 from the upstream side 2131 to the downstream side 2132. The plurality of injection ports 2109 are configured to accelerate a cooling fluid F as the cooling fluid F passes therethrough from the upstream side 2142 to the downstream side 2144 of the distributor plate 2110. To that end, the injection ports 2109 have outlets 2143 on the downstream side 2144 of the distributor plate 2110. The impingement target plate 2112 is arranged adjacent the distributor plate 2110 such that the accelerated cooling fluid F is directed onto the upstream side 2131 of the impingement target plate 2112 and thereafter through the extraction ports 2108 to the downstream side 3132 of the impingement target plate 2112. To that end, the extraction ports 2108 have inlets 2133 on the upstream side 2131 of the impingement target plate 2112. According to the present invention, the upstream side 2131 of the impingement target plate 2112 and/or at least one extraction port 2108 in the plurality of extraction ports is provided with a plurality of protrusions 2104, 2105, 2106 configured to increase a conductive surface area of the upstream side 2131 of the impingement target plate 2112 and/or a conductive surface area within the at least one extraction port 2108 in the plurality of extraction ports, respectively.

According to the examples of FIGS. 25, 27, and 28, a subset of protrusions 2104, 2105 in the plurality of protrusions 2104, 2105, 2106 on the upstream side 2131 of the impingement target plate 2112 have port-scale dimensions similar to dimensions of the injection and extraction ports 2109, 2108. The port-scale protrusions 2104, 2105 on the upstream side 2131 of the impingement target plate 2112 are arranged about areas 2116 immediately opposite the outlets 2143 of respective injection ports 2109 in the plurality of injection ports such that the accelerated cooling fluid is directed onto the areas 2116 surrounded by the port-scale protrusions 2104, 2105 and then around the port-scale protrusions 2104, 2105 prior to being directed through the extraction ports 2108.

In some examples, as shown in FIGS. 25 and 28, the port-scale protrusions 2104 have a curved diamond shape in cross section. FIG. 28 shows how a given extraction port 2108 is defined along first and second axes 2154, 2156 that are perpendicular to one another. A major axis 2158 of a first port-scale protrusion 2104a is aligned with the first axis 2154 of the given extraction port 2108. A major axis 2160 of a second port-scale protrusion 2104b is aligned with the second axis 2156 of the given extraction port 2108. Due to the curved diamond shape of each protrusion 2104a, 2104b, an elliptical flow path 2162 is defined between the first and second port-scale protrusions 2104a, 2104b (i.e., a flow path having the shape of a petal of the irregularly shaped flower defined between the port-scale protrusions 2104). In the example shown here, micro-scale protrusions 2106 are formed within the elliptical flow path 2162 on the upstream side 2131 of the impingement target plate 2112. This way, heat is transferred not only by fluid flowing past the projecting surfaces of the port-scale protrusions 2104, but also by fluid flowing past the projecting surfaces of the micro-scale protrusion 2106 between the port-scale protrusions 2104.

According to the examples of FIGS. 25, 28, 29, and 31, a subset of protrusions 2106 in the plurality of protrusions 2104, 2105, 2106 on the upstream side 2131 of the impingement target plate 2112 and/or in the at least one extraction port 2108 have micro-scale dimensions.

As shown in FIGS. 25 and 28, the micro-scale protrusions 2106 on the upstream side 2131 of the impingement target plate 2112 are elliptical in cross section. In some examples, as shown in FIG. 28, a subset of the micro-scale protrusions 2106 on the upstream side 2131 of the impingement target plate 2112 each have a major axis 2148 that is aligned radially with respect to a given extraction port 2108 in the plurality of extraction ports. In other words, subsets of the micro-scale protrusions 2106 radiate outwardly from a given extraction port 2108 that they surround. Fluid flows around each elliptical micro-scale protrusion 2106, which may act as a hydrofoil, and into the extraction port 2108. The micro-scale protrusions 2106 may have their axes directly along an extension of a radius 2150 of the extraction port 2108. Alternatively, the micro-scale protrusions 2106 may have their axes arranged along an arced path 2152 that is more or less radially aligned with the extraction port 2108.

As noted hereinabove and as shown ion FIG. 28, the micro-scale protrusions 2106 on the upstream side 2131 of the impingement target plate 2112 project from the upstream side 2131 of the impingement target plate 2112 at various heights. The height of the micro-scale protrusions 2106a on the upstream side 2131 of the impingement target plate 2112 closest to the outlet 2143 of a given injection port 2109 (i.e., near jetted-on area 2116) is less than the height of the micro-scale protrusions 2106b on the upstream side 2131 of the impingement target plate 2112 closest to the inlet 2133 of a given extraction port 2108 in the plurality of extraction ports.

According to the example of FIG. 31, a lip 2140 may be provided on the downstream side 2132 of the impingement target plate 2112 adjacent an outlet 2135 of at least one extraction port 2108 in the plurality of extraction ports.

As shown in FIGS. 25 and 26, the impingement cooling device 2100 further comprises a baseplate 2102, and the distributor plate 2110 and the impingement target plate 2112 are coupled to and project perpendicularly with respect to the baseplate 2102.

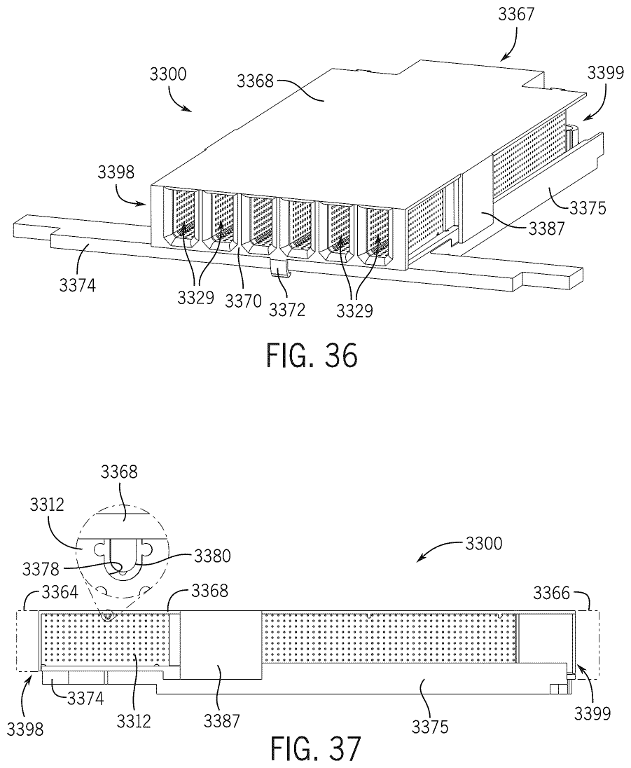

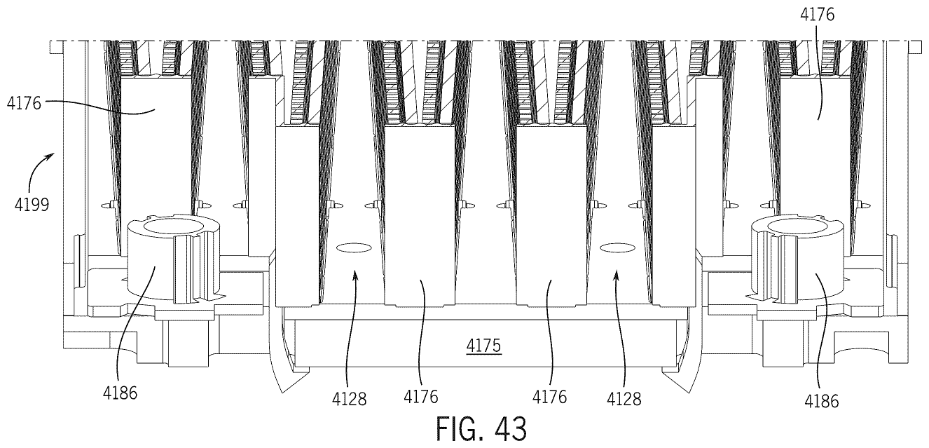

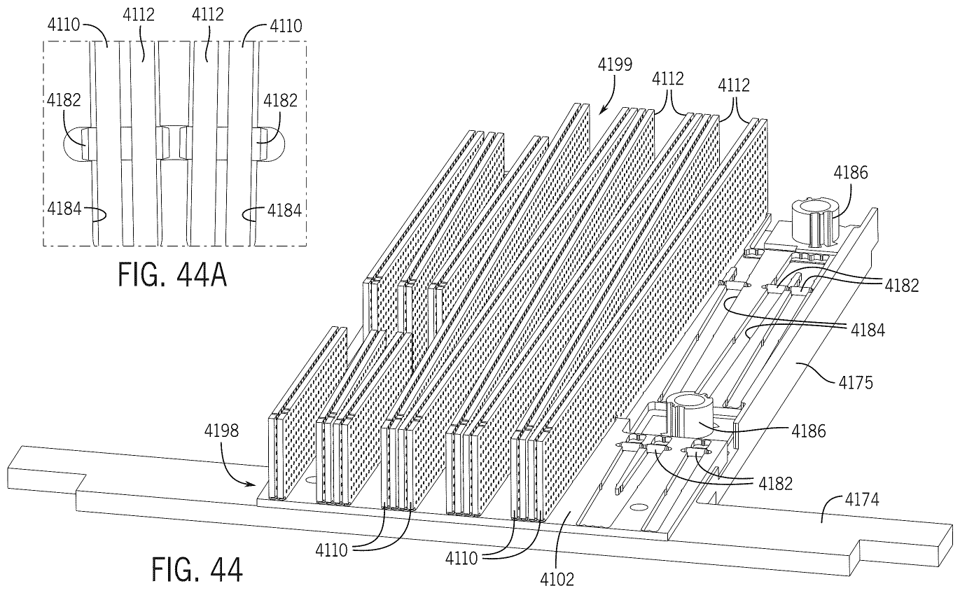

As discussed hereinabove with respect to FIGS. 4-14, the baseplate 2102 (see FIG. 25) is configured to be situated over an object to be cooled. The baseplate 2102 can be placed over a support plate 2175 (see also support plate 3375 in FIG. 36; support plate 4175 in FIG. 44), which is in turn placed over a lid covering the object (see, for example, heat spreader lid 135 in FIG. 13), or the baseplate 2102 can be the support plate and/or the lid itself. Thus, as used herein, the term “baseplate” can refer to any one of the above-noted components (baseplate, support plate, or lid) or to a combination of two or all three of the noted components.

In some examples, the object to be cooled is an integrated circuit.

As shown in FIG. 30, the baseplate 2102, 2175 may comprise a vapor chamber or a heat pipe 2136.

### 2.2.2.6. Improved Flow Uniformity and Reduced Pressure Drop

Features to improve flow uniformity and reduce pressure drop include converging and diverging inlet and outlet channels, respectively. In FIG. 32, the impingement inlet is shown, where the fluid comes in, passes through the impingement target plates 3212 and exits via an outlet channel 3228, which is defined between diverging impingement target plates 3212. This results in reduced pressure drop and improved flow uniformity.

More specifically, the distributor plate 3210 is a first distributor plate 3210a and the impingement target plate 3212 is a first impingement target plate 3212a, and the impingement cooling device 3200 further comprises a second distributor plate 3210b coupled to and projecting generally perpendicularly (e.g., 80-100 degrees, 85-95 degrees, 87-93 degrees, 89-91 degrees, or 90 degrees) with respect to the baseplate 3202, the second distributor plate 3210b including an upstream side 3242, a downstream side 3244 opposite the upstream side 3242, and a plurality of injection ports 3209 extending through the second distributor plate 3210b from the upstream side 3242 to the downstream side 3244 and configured to accelerate the cooling fluid as the cooling fluid passes therethrough from the upstream side 3242 to the downstream side 3244 of the second distributor plate 3210b. A second impingement target plate 3212b is coupled to and projects perpendicularly with respect to the baseplate 3202, the second impingement target plate 3212b including an upstream side 3231, a downstream side 3232 opposite the upstream side 3231, and a plurality of extraction ports 3208 extending through the second impingement target plate 3212b from the upstream side 3231 to the downstream side 3232. The second impingement target plate 3212b is arranged adjacent the second distributor plate 3210b such that the accelerated cooling fluid is directed onto the upstream side 3231 of the second impingement target plate 3212b and thereafter through the extraction ports 3208 to the downstream side 3232 of the second impingement target plate 3212b. The first and second impingement target plates 3212a, 3212b are arranged laterally beside one another with the downstream side 3232 of the first impingement target plate 3212a opposing the downstream side 3232 of the second impingement target plate 3212b so as to form an outlet channel 3228 therebetween. The baseplate 3202 and the outlet channel 3228 extend in a longitudinal direction L.

In the example of FIG. 31, the outlet channel 2128 maintains a given lateral width along the longitudinal direction L. This is because the impingement target plates 2112a, 2112b defining the outlet channel 2128 are parallel to one another. In contrast, in FIG. 32, the outlet channel 3228 varies in lateral width W along the longitudinal direction L. This is because the first and second impingement target plates 3212a, 3212b diverge from one another in the longitudinal direction L. In other words, in the embodiment of FIG. 32, the first distributor plate 3210a is non-parallel with the second distributor plate 3210b and/or the first impingement target plate 3212a is non-parallel with the second impingement target plate 3212b.

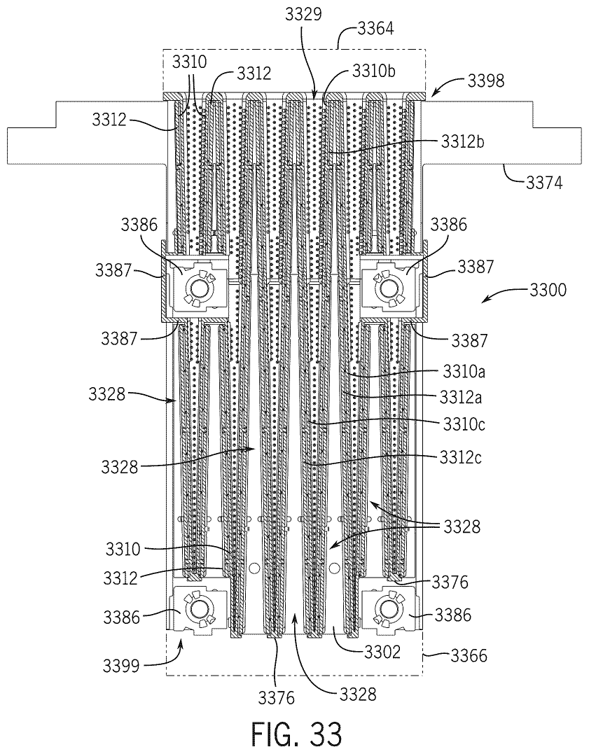

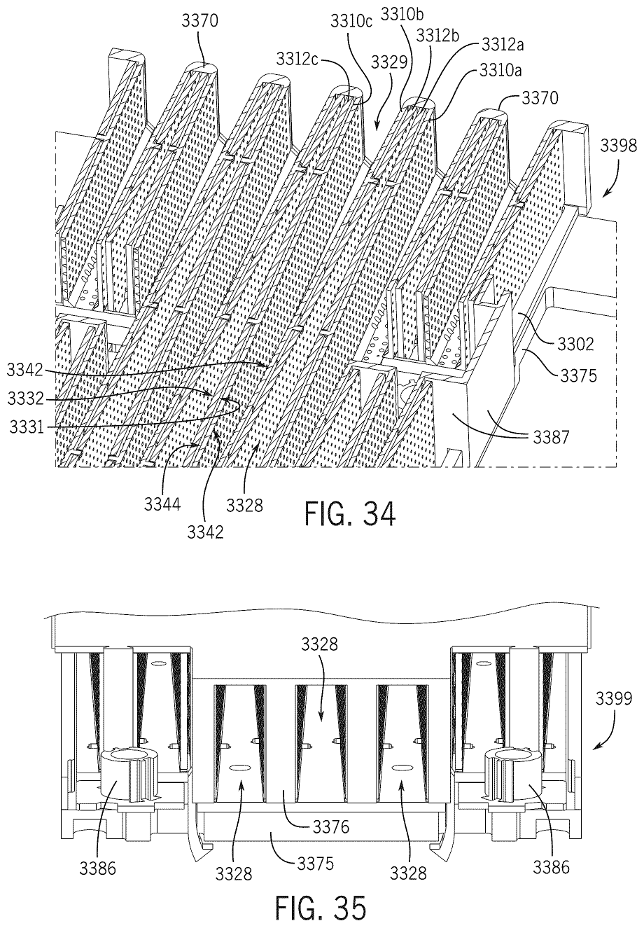

FIGS. 33-40 show another embodiment of an impingement cooling device 3300 according to the present disclosure. Similar to the example of FIG. 32, as best shown in FIG. 34, the impingement cooling device 3300 has first and second distributor plates 3310a, 3310b with injection ports that accelerate cooling fluid onto respective first and second target impingement plates 3312a, 3312b, each of which comprises extraction ports that lead to a common outlet channel 3328. The first and second distributor plates 3310a, 3310b and first and second target impingement plates 3312a, 3312b may provided with any of the features discussed hereinabove with respect to FIGS. 25-32, which features will not be discussed further herein for the sake of brevity.

Still referring to FIG. 34, a third distributor plate 3310c is coupled to and projects perpendicularly with respect to the baseplate 3302. The third distributor plate 3310c includes an upstream side 3342, a downstream side 3344 opposite the upstream side 3342, and a plurality of injection ports extending through the third distributor plate 3110c from the upstream side 3142 to the downstream side 3144 and configured to accelerate the cooling fluid as the cooling fluid passes therethrough from the upstream 3142 side to the downstream side 3144 of the third distributor plate 3110c. A third impingement target plate 3312c is coupled to and projects perpendicularly with respect to the baseplate 3302. The third impingement target plate 3312c includes an upstream side 3331, a downstream side 3332 opposite the upstream side 3331, and a plurality of extraction ports extending through the third impingement target plate 3312c from the upstream side 3331 to the downstream side 3332. The third impingement target plate 3312c is arranged adjacent the third distributor plate 3310c such that the accelerated cooling fluid is directed onto the upstream side 3331 of the third impingement target plate 3312c and thereafter through the extraction ports to the downstream side 3332 of the third impingement target plate 3312c. The second and third distributor plates 3310b, 3310c are arranged laterally beside one another with the upstream side 3342 of the second distributor plate 3310b opposing the upstream side 3342 of the third distributor plate 3310c so as to form an inlet channel 3329 therebetween.

As shown in FIG. 33, the inlet channel 3329 is configured to receive cooling fluid via an inlet end 3398 of the impingement cooling device 3300. The outlet channel 3328 is configured to direct the cooling fluid to an outlet end 3399 of the impingement cooling device 3300. The inlet channel 3329 has a width that decreases from the inlet end 3398 toward the outlet end 3399 of the impingement cooling device 3300. The outlet channel 3328 has a width that increases from the inlet end 3398 toward the outlet end 3399 of the impingement cooling device 3300. In fact, a plurality of pairs of distributor plates 3310 and impingement target plates 3312 are provided connected to the baseplate 3302, forming a plurality of inlet channels 3329 and outlet channels 3328 therebetween, each of which varies in width as described hereinabove. Thus, each inlet channel in the plurality of inlet channels 3329 has a width that decreases from the inlet end 3398 toward the outlet end 3399 of the impingement cooling device 3300. Each outlet channel in the plurality of outlet channels 3328 has a width that increases from the inlet end 3398 toward the outlet end 3399 of the impingement cooling device 3300. Having the inlet channels 3329 be wider at the inlet end 3398 of the impingement cooling device 3300 prevents maldistribution of fluid in the impingement cooling device 3300 and reduces pressure drop, thereby improving cooling efficiency.

The plurality of inlet channels 3329 are configured to receive cooling fluid via the inlet end 3398 of the impingement cooling device 3300, and the plurality of outlet channels 3328 are configured to direct the cooling fluid to the outlet end 3399 of the impingement cooling device 3300. To that end, as shown in FIG. 33, the impingement cooling device 3300 may further comprise an inlet manifold 3364 coupled each inlet channel in the plurality of inlet channels 3329 and an outlet manifold 3366 coupled to each outlet channel in the plurality of outlet channels 3328. The inlet manifold 3364 is configured to provide cooling fluid from a cooling fluid source (described herein below with respect to FIGS. 57-60) to the plurality of inlet channels 3329. The outlet manifold 3366 is configured to provide the cooling fluid from the plurality of outlet channels 3328 to an exhaust area (also described herein below with respect to FIGS. 57-60). As shown in FIG. 36, the impingement cooling device 3300 may include a cover plate 3368 placed over the distributor and target impingement plates. FIGS. 33 and 34 therefore are cross-sectional views taken just below the cover plate 3368 so that the inlet and outlet channels 3329, 3328 can be seen. An end cap 3370 closes off the near ends of the outlet channels 3328, while leaving the entrances to the inlet channels 3329 open to the inlet manifold, which would sit immediately in front of and would be fluidically connected to the inlet end 3398 of the device. FIG. 36 also shows how the cover plate 3368 and end cap 3370 can be one piece (i.e., a manifold 3367), and can include a clip 3372, which is configured to attach the manifold 3367 to a bar-shaped portion 3374 of a support plate 3375 to be placed over the object to be cooled. Using a clip 3372 means the manifold 3367 does not need to be bolted to the baseplate 3302. FIG. 35 meanwhile shows the outlet end 3399 of the device, where an end cap 3376 can be provided over ends of the inlet channels 3329 to prevent fluid from leaving the device without going through the outlet channels 3328. FIG. 37 shows how a female cutout 3378 formed in the top edge of impingement target plate 3312 receives a male extrusion 3380 formed on the bottom of the cover plate 3368 to lock the two pieces together. This connection also prevents longitudinal movement of the cover plate 3368 with respect to the impingement target plate 3312.

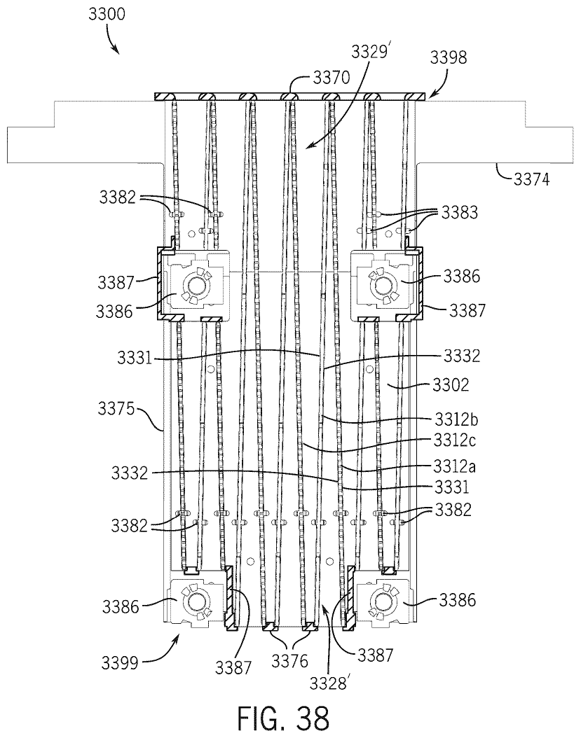

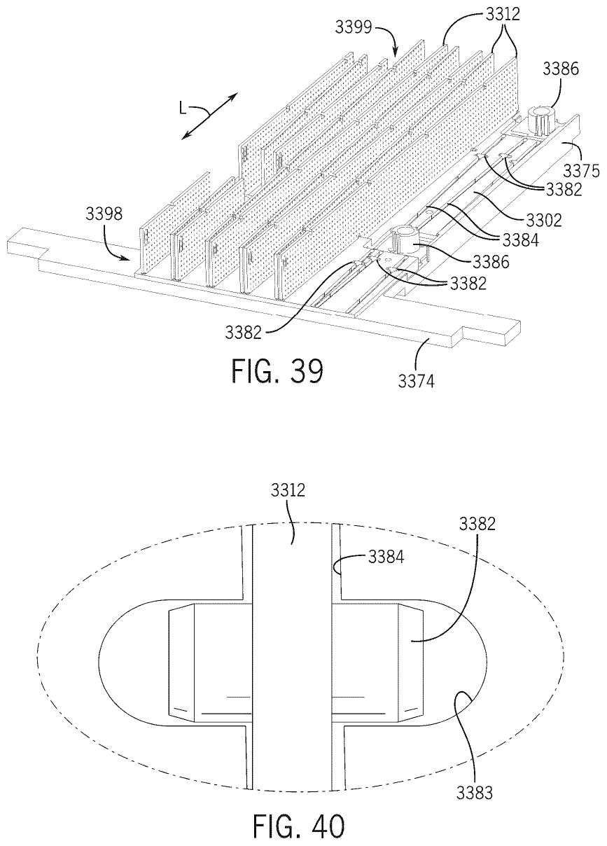

Turning to FIGS. 38 and 39, a part of the impingement cooling device 3300 is shown without the portions that make up the distributor plates 3310. This allows the baseplate 3302 to be seen more clearly. Further, it allows alignment pins 3382 to be seen. The alignment pins 3382 are situated within recesses 3383 (see also FIG. 40) formed in the top surface of the baseplate 3302. Longitudinal grooves 3384 are also formed in the baseplate 3302. Lower ends of the impingement target plates 3312 are slotted into the grooves 3384, which lower ends are provided with female cutouts that receive the alignment pins 3382 therein so as to locate the impingement target plates 3312 in the longitudinal direction L. A top view of an impingement target plate 3312 aligned over an alignment pin 3382 is provided in FIG. 40. In some examples, soft solder paste within the grooves 3384 can be used to bond the impingement target plates 3312 to the baseplate 3302.After the impingement target plates 3312 are correctly located on and attached to the baseplate 3302, the distributor plates 3310 may be added to the device. In the present example, the distributor plates 3310 are integrally formed with the cover plate 3368 and end caps 3370 and 3376, and thus a single manifold 3367 (FIG. 36) including all these components may be placed over the baseplate 3302 and impingement target plates 3312. As noted with respect to FIGS. 36 and 37, this step may include aligning male and female features on the parts and/or clipping the housing/manifold 3367 (comprising the distributor plates 3310, cover plate 3368, and end caps 3370 and 3376) to the bar 3374 and/or baseplate 3302.

In another example, the assembly of FIG. 38 can be used without the distributor plates 3310. In some cases, the distributor plates are not required for adequate cooling, and instead heat is transferred as it passes through the extraction ports of the impingement target plates 3312 (which in this case function as distributor plates as well). This solution provides a very low pressure drop across the device, while still removing heat from the object to be cooled. Thus, the present disclosure contemplates an impingement cooling device 3300 comprising a first plate 3312a including an upstream side 3331, a downstream side 3332 opposite the upstream side 3331, and a first plurality of ports extending through the first plate 3312a from the upstream side 3331 to the downstream side 3332 and configured to accelerate a cooling fluid as the cooling fluid passes therethrough from the upstream side 3331 to the downstream side 3332 of the first plate 3312a. A second plate 3312b includes an upstream side 3331, a downstream side 3332 opposite the upstream side 3331, and a second plurality of ports extending through the second plate 3312b from the upstream side 3331 to the downstream side 3332 and configured to accelerate the cooling fluid as the cooling fluid passes therethrough from the upstream side 3331 to the downstream side 3332 of the second plate 3312b. The first plate 3312a is arranged adjacent the second plate 3312b such that the accelerated cooling fluid from the first plurality of ports is directed onto the downstream side 3332 of the second plate 3312b and such that accelerated cooling fluid from the second plurality of ports is directed onto the downstream side 3332 of the first plate 3312a. The first plate 3312a is non-parallel with the second plate 3312b, thereby forming a diverging outlet channel 3328′. Plate 3312b and adjacent non-parallel plate 3312c form a converging inlet channel 3329′. The converging inlet channel 3329′ and diverging outlet channel 3328′ have the benefits of channels 3329, 3328 described hereinabove.

As best shown in FIG. 39, it may be desirable to provide posts 3386 for receiving bolts that are used to bolt the support plate 3375 into a server. To ensure that cooling fluid flows through the distributor plates 3310 and impingement target plates 3312 instead of around the posts 3386, cover plates 3387 may be provided around each post 3386, as shown in FIGS. 33, 34, and 38.

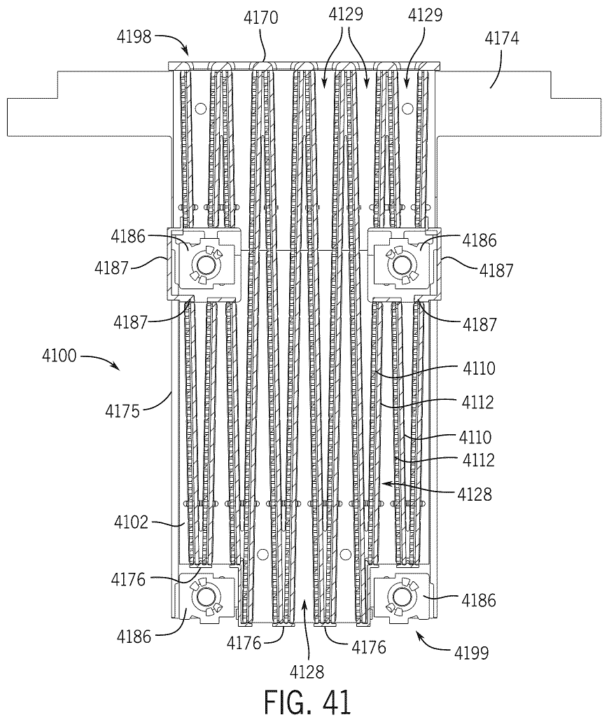

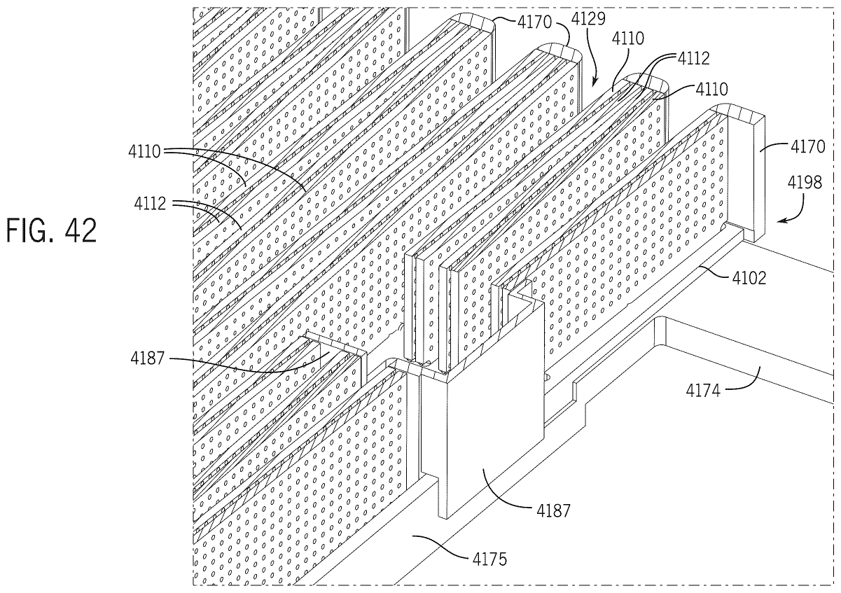

In the impingement cooling device 3300 of FIGS. 33-40, the housing/manifold 3367 is formed of a non-conductive material such as plastic, polylactic acid (PLA), or nylon, and the impingement target plates 3312 are formed of a conductive material such as copper or aluminum. In contrast, in the exemplary impingement cooling device 4100 of FIGS. 41-44, both the distributor plates 4110 and the impingement target plates 4112 are made of a conductive material such as copper or aluminum. The flow of fluid through this impingement cooling device 4100 is shown by arrows and it can be seen that fluid enters the inlet channels 4129, which are defined between adjacent distributor plates 4110, via end cap 4170 at the inlet end 4198 of the impingement cooling device 4100. End cap 4170 may be made of plastic or another non-conductive material, or of a conductive material such as copper or aluminum, noting that its purpose it not to dissipate heat, but rather to guide fluid through the correct channels. Fluid flows through the plurality of injection ports in the distributor plates 4110, which may be designed like any of the injection ports described hereinabove. Fluid then contacts the impingement target plates 4112 and flows through extraction ports therein (again, designed like any of the extraction ports described herein above) into outlet channels 4128. Fluid then flows out of the outlet end 4199 of the impingement cooling device 4100 via the outlet channels 4128. The ends of inlet channels 4129 proximate the outlet end 4199 of the device are provided with endcaps 4176, which may be made of plastic or another non-conductive material or a conductive material such as copper or aluminum, and which serve to ensure that fluid in the inlet channels 4129 flows through the distributor plates 4110 and impingement target plates 4112 instead of out of the opposite ends of the inlet channels 4129.

Portions of the impingement cooling device 4100 not described explicitly herein are similar to that of impingement cooling device 3300, such as the posts 4186 for receiving bolts to attach the device to a server and plates 4187 that surround these posts 4186 and ensure air flows through the distributor plates 4110 and impingement target plates 4112 instead of out of the device. Other components not specifically described herein with respect to impingement cooling device 4100 are the same as or similar to those of impingement cooling device 3300, but start with “41” instead of “33”.

Besides the materials used, the other main difference between impingement cooling devices 3300 and 4100 is that baseplate 4102 is provided with wider grooves 4184 in its upper surface, as shown in FIG. 44. Grooves 4184 are configured to receive the lower ends of both conductive plates 4110 and 4112 therein. Pins 4182 are located cross-wise within these grooves 4184. Female cutouts in the bottom ends of the distributor plates 4110 and impingement target plates 4112 are configured to slot around these pins when the plates 4110, 4112 are aligned within the grooves 4184, thereby locating the plates longitudinally. FIG. 44A shows how a pair of one distributor plate 4110 and one impingement target plate 4112 can both be located within the same groove 4184 and slotted over the same pin 4182.

Some benefits of using copper (or other conductive material) for the distributor plates 4110 is that the distributor plates 4110 reject heat similar to the impingement target plates 4112. That is, while accelerating the air through the injection ports, the conductive material of the distributor plates 4110 remove heat from the fluid.

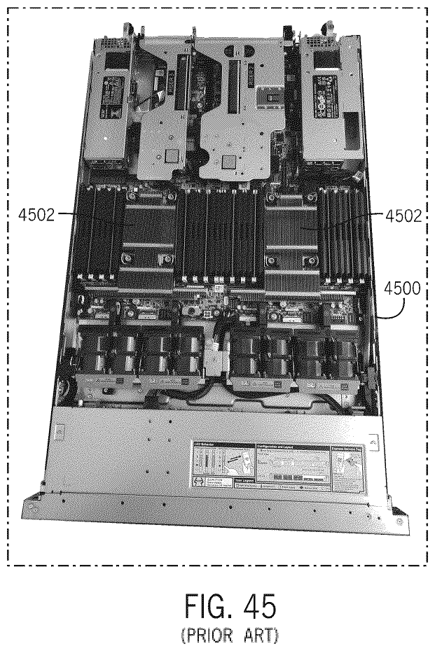

FIGS. 45-49 show how an impingement cooling device can be installed into a server. Specifically, the impingement cooling device 3300 will be used as an example, but it will be understood that a similar method of installation applies for other impingement cooling devices described herein.

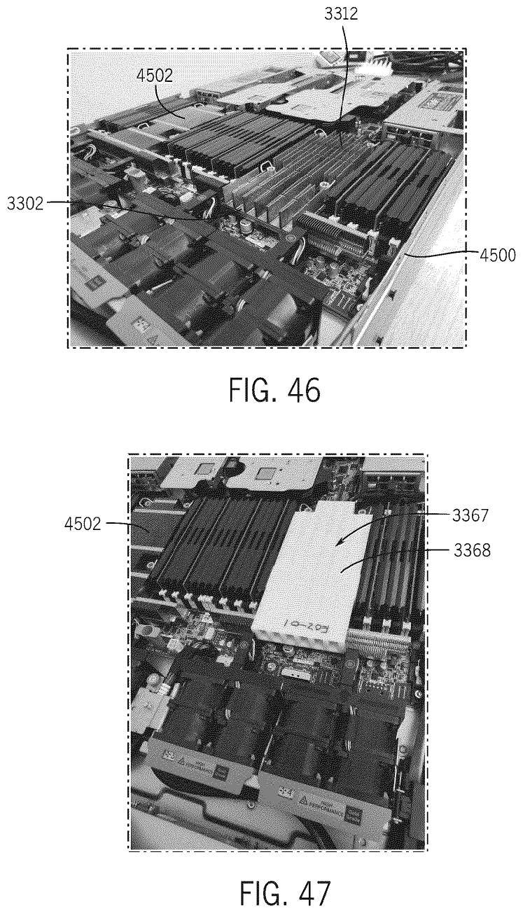

FIG. 45 shows a stock server 4500 with stock cooling devices 4502 installed therein. FIG. 46 shows the server 4500 with one of the stock cooling devices 4502 still installed, but the other removed and replaced by the baseplate 3302 and impingement target plates 3312 of the impingement cooling device 3300 of the present disclosure. Similar to how the IC was clipped onto the bottom of the stock cooling device 4502, the IC may be clipped onto the bottom of the impingement cooling device 3300 of the present disclosure before the baseplate 3302 and impingement target plates 3312 are installed in the server 4500. FIG. 47 shows the server 4500 with the housing/manifold 3367 (including distributor plates 3310, cover plate 3368, etc.) installed over the impingement target plates 3312.

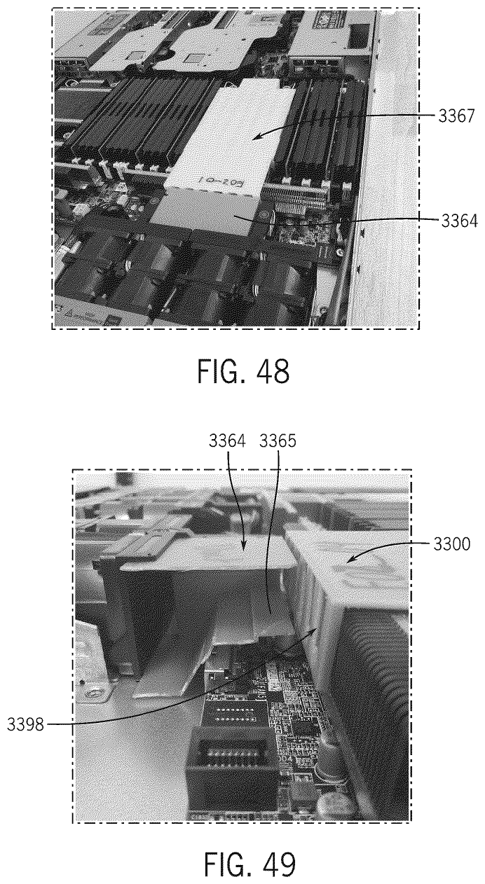

FIG. 48 shows an inlet manifold 3364 installed at the inlet end of the housing/ manifold 3367. As shown in FIG. 49, the inlet manifold 3364 is in fluid communication with the inlet end 3398 of the impingement cooling device 3300. The inlet manifold 3364 includes a stepped lower plate 3365 that fits over electrical components (for example, voltage regulators, connectors, etc.) in the server 4500, while maximizing cross-sectional area for flow of cooling air through the inlet manifold 3364. The inlet manifold 3364 can be taped, clipped, or otherwise mounted to the inlet end 3398 of the impingement cooling device 3300 to provide a better seal thereto and prevent cooling fluid from escaping into the surroundings In other examples, the inlet manifold 3364 and the housing/manifold 3367 are formed as one solid structure or are friction welded together.

### 2.2.2.7. Other Target Surfaces

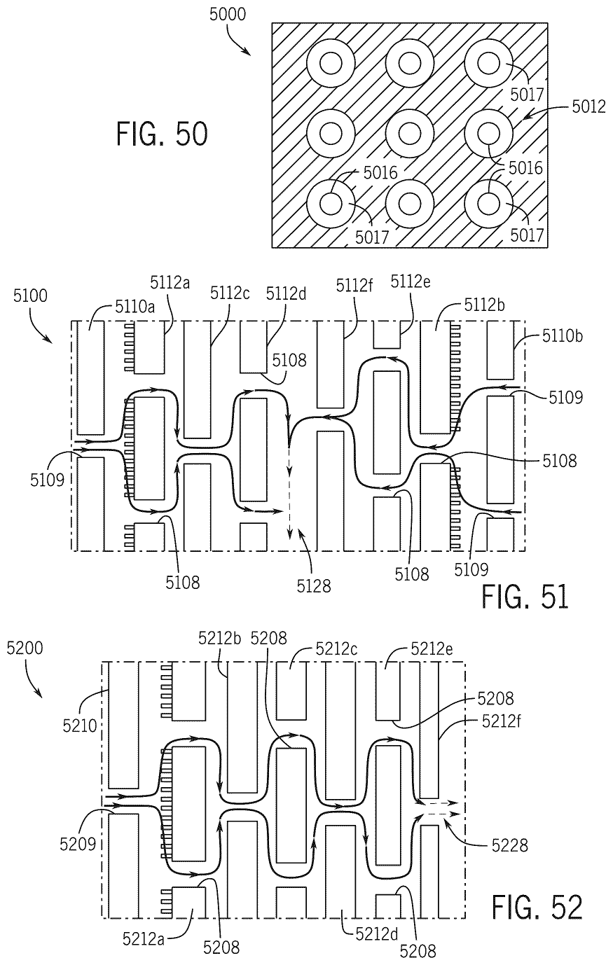

There are several additional impingement surface configurations for TJI. The impingement surface (on the impingement target plate 3312, 4112 or baseplate 3302, 4102) may be a non-planar face. This face may be concave up or concave down or an irregular target surface. The impingement cooling device 3300, 4100 may also cool multiple heat sources with a single impingement cooling device. The impingement cooling device 3300, 4100 may also impact a semi-porous target surface 5012 as shown in FIG. 50. Here, the circles 5016 represent the area where fluid is jetted onto the target surface. The areas of solid fill 5017 surrounding the location of each jet 5016 represent high heat conductive material such as aluminum or copper. After impacting the target surface comprising solid fill 5017, the fluid moves through the porous conductive material 5012, which can be metallic foam, porous copper, or an etched or sintered material. This can further improve heat transfer rates by the fluid moving through a plethora of small-scale orifices or cracks in the porous conductive material 5012.

### 2.2.2.8. TJI Variations

There are also several TJI variations including an impingement cooling device 5100 as shown in FIG. 51 having vertical distributor plates 5110a, 5110b that accelerate fluid through injection ports 5109, which fluid impacts vertical impingement target plates 5112a, 5112b and passes through the impingement target plates 5112a, 5112b to one or more additional vertical impingement target plates 5112c, 5112d, 5112e, 5112f. The additional impingement target plates 5112c-f each have extraction ports 5108, some of which effectively act as injection ports for the subsequent impingement target plate. In this way, the impingement target plates 5112a-f serve as dual-function impingement target plates and distributor plates. The extraction ports 5108 eventually direct air to a common outlet channel 5128, via which fluid exits the device. This device may also contain a number of area enhancement variations including webbed fins, pin fins, and micro-scale area enhancement as described hereinabove. The vertical impingement target plates 5112a-f may also have varying thicknesses. Further, the distributor plates 5110a, 5110b and/or the impingement target plates 5112a-f may be made of a conductive material to provide for additional heat dissipation.

Another impingement cooling device 5200 shown in FIG. 52 may contain one or more distributor plates 5210 having injection ports 5209 that accelerate fluid onto a vertical impingement target plate 5212a, after which the fluid passes through a plurality of subsequent impingement target plates 5212b-f to a common outlet 5228. Again, many of the extraction ports 5208 also act as injection ports for the next impingement target plate in the series, and, as such, structurally, the impingement target plates' extraction ports 5208 may be configured to accelerate fluid onto the adjacent downstream impingement target plate. In this way, the impingement target plates 5212a-e serve as dual-function impingement target plates and distributor plates. The vertical impingement target plates may also have varying thicknesses. Further, the distributor plate 5210 and/or the impingement target plates 5212a-f may be made of a conductive material to provide for additional heat dissipation.

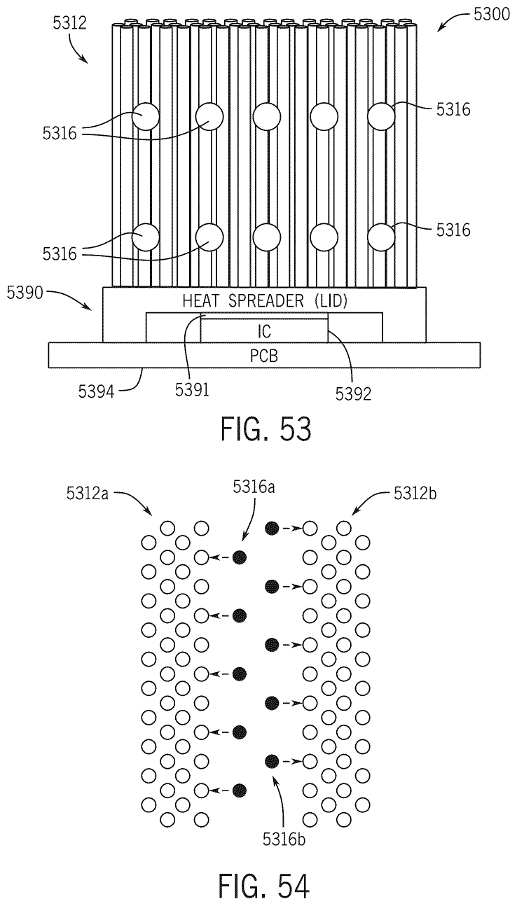

FIGS. 53 and 54 show another impingement cooling device 5300 in which fluid may be accelerated onto vertical cylinders 5312 instead of a flat impingement target plate. These vertical cylinders 5312 are arranged to provide a circuitous flow path and may contain micro-scale or macro-scale area enhancements including divots/slivers (i.e., non-smooth surfaces) or pin fins to increase heat transfer area. FIG. 53 shows the vertical cylinders 5312 attached to a heat spreader lid 5390, which is bonded by way of thermal interface material 5391 to an IC 5392, in turn supported on a PCB 5394. The circles 5316 represent the locations at which fluid would be jetted onto the cylinders 5312 by way of injection ports in a distributor plate. FIG. 54 shows a top-down schematic of how two pluralities of jets 5316a, 5316b could impact two groups of vertical cylinders 5312a, 5312b, for example utilizing adjacent distributor plates with a common inlet channel as described hereinabove.

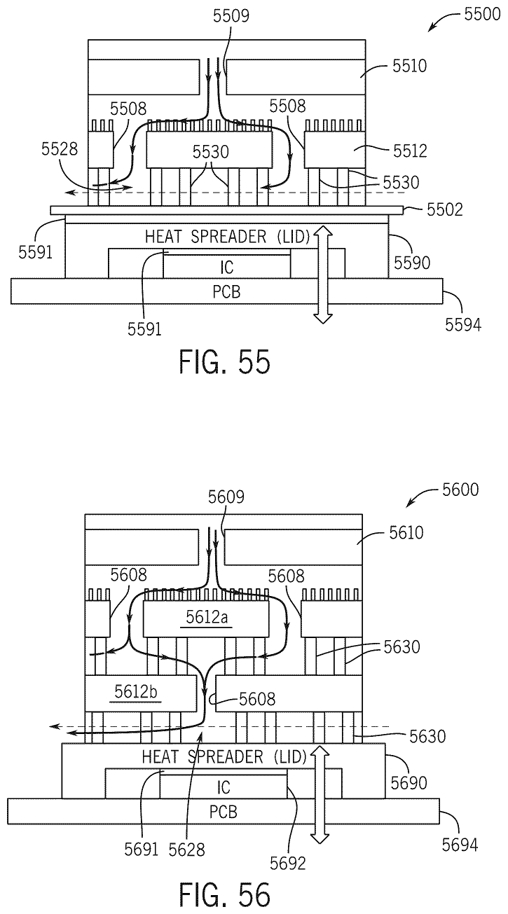

Another impingement cooling device 5500 involves turning the device ninety degrees such that it is more compact. This also maximizes the effectiveness of the cooling fluid by requiring the cooling fluid to exit closest to the heat generating device. As shown in FIG. 55, the baseplate 5502 can be attached to the lid 5590 with a TIM 5591, or it may be integrated into the lid 5590 (see FIG. 56) to further reduce the thermal resistance network. The fluid is routed from a manifold to the distributor plate 5510, where it enters an injection port 5509 that increases the velocity towards the impingement target plate 5512. The jet impacts the impingement target plate 5512, turning laterally and then axially to move through the extraction ports 5508, which form jets that impact the baseplate 5502. In this way, the impingement target plate 5512 serves as a dual-function impingement target plate and distributor plate. In FIG. 55, the fluid then exits through a common return channel 5528 that has thermally conductive pins 5530 that disrupt the flow to improve heat transfer as well as improve conduction to the impingement target surface and increase heat transfer area. Multiple layers of this structure may be added to further increase the surface area and flow path. Heat pipes may be added in any one or more of these layers, thereby connecting the baseplate 5502 to the impingement target plates 5512. In the impingement cooling device 5600 of FIG. 56, for example, the jetted fluid passes through first impingement target plate 5612a, impacts the top of second impingement target plate 5612b, turns laterally and then passes through extraction port 5608 before exiting in a common return channel 5628 as shown by the arrows. As with the example of FIG. 55, thermally conductive pins 5630 may be provided: here, between each of the impingement target plates 5612a and 5612b and between the impingement target plate 5612b and the lid 5690. Both examples in FIGS. 55 and 56 may be provided with micro-scale or macro-scale area enhancements as described hereinabove.

Further connections between the lid and the baseplate may be added to improve conduction to the impingement target surface. Heat pipes may also be connected to the target surface and the main body in contact with the heat generating device, e.g., the lid 5690 in FIG. 56. The heat pipe connection improves conduction heat transfer to the target surface. The impingement cooling devices of FIGS. 55 and 56 can contain any combination of previously mentioned area enhancement, improved conduction methods, alignment or materials which will be discussed next.

### 2.3. Materials

Materials can be chosen for particular applications to avoid thermal warping and/or cracking. These materials may include but are not limited to aluminum nitride, copper/aluminum, 3D printed alloys, castable alloys, and non-electrically conductive but thermally conductive alloys. Ceramics like aluminum nitride for heat spreader can be soldered to the IC and/or the baseplate. Other methods can be used to mechanically bond materials together. These include binary material for fins. The binary material may be composed of two or more materials with different coefficients of thermal expansion. The difference in coefficients of thermal expansion may result in uneven expansion of the materials, resulting in a change in shape or orientation of the fins, thereby opening or constricting a particular flow path. The impingement target plate and baseplate may be fabricated from a high thermal conductivity material, such as copper, then plated in a secondary material which would provide corrosion resistance or improved solderability, such as nickel.

### 2.4. Bonding Methods

Bonding methods for attaching the vertical impingement target plates (and, in some examples the distributor plates) to the baseplate include using a hard or soft solder, friction welds, conductive adhesives, mechanical fastening and thermal interference fit accomplished by cooling one body while heating the other and then press fitting it in. Manufacturing methods for the extraction ports on the impingement target plates include but are not limited to: photo etching, laser cutting, stamping, casting, machining, water jetting, and 3D printing.

Bonding methods for attaching the baseplate to the device to be cooled (e.g. the IC) could include the use of hard or soft solders, friction welds, conductive adhesives, mechanical fastening, thermal greases, thermal interface pads, graphene or graphite thermal interface pads, indium thermal interface pads, and more.

### 2.5. Maintenance and Servicing

The impingement cooling devices disclosed herein may also contain features for maintenance/servicing. These could include a maintenance port to blow compressed air in and clean out the cooling system. This would blow out dust and open clogged impingement jets. Optionally, the blowout air could flow in the reverse direction of the typical flow path through the device. Optionally, pressure relief ports built into the impingement cooling device could open to release excess air pressure during system blowout. System cleanout procedures could be conducted while the impingement cooling device is attached to the target IC device or while the impingement cooling device is removed from the target IC device.

### 2.6. Controls

The flow rate to the TJI, RJI, or other chip-level subsystem can be controlled externally or using controls integrated into the server-level subsystem 2200. The impingement cooling device can be outfitted with built-in measurement ports for measuring control variables such as pressure drop across the device, inlet and outlet air temperatures, baseplate temperature, and local airflow rate. In some examples, the pressure drop of the device may alternatively or additionally be monitored by monitoring the amperage of the air delivery mechanism for a given pulse width modulation signal or other signal.

### 3. Server-Level Sub System

The ambient temperature air routed into and hot air routed out of the building starts with separating the airflow streams on the server 4500. FIG. 57 provides one example arrangement of the server-level subsystem 2200 including a chip-level impingement cooling device 2100, which cools two CPUs 5710 (or GPUs or other ICs) of the server 4500. Although the impingement cooling device 2100 of FIG. 21 is shown, it should be understood that any of the impingement cooling devices 200, 1500, 3200, 3300, 4100, 5000, 5100, 5200, 5300, 5500, 5600 disclosed herein could be used. Upstream and downstream fans 5702, 5704 provide the required airflow to the chip-level impingement cooling device 2100. Airflow through the chip-level impingement cooling device 2100 is segregated from the surrounding air by use of upstream and downstream ducts 5706, 5708. There are several segregation methods for separating the airflow streams. An air delivery device is used to move the air, in which there are also several methods of delivering the air to the cooling device and extracting that hot air from the server 4500. A number of optional attachments including sound abatement, controls, and redundancy are also possible. The inventions around these components will be described below.

As noted, the chip-level cooling device can be any of the impingement cooling devices 200, 1500, 2100, 3200, 3300, 4100, 5000, 5100, 5200, 5300, 5500, 5600 described herein. The impingement cooling device is an example of a chip-level subsystem configured to cool, for example, an integrated circuit. For the sake of brevity, these impingement cooling devices will hereinafter be referred to as a “chip-level cooling device 2100” for purposes of discussing the server-level, rack-level, and facility-level subsystems. It should be understood that the server-level, rack-level, and facility-level subsystems could be implemented with chip-level cooling devices other than the RJI and TJI devices disclosed herein, such as a stock cooling device 4502 like that shown in FIG. 45. However, there may advantages to using an RJI or TJI device in the server-level, rack-level, and facility-level subsystems, as will be discussed below.

### 3.1. Flow Segregation Methods

Server airflow segregation methods can be broken into type I-III: I) no segregation, II) half segregation, and III) full segregation. In this case, the segregation of air is defined as a collection of the air which passes through the chip-level cooling device 2100 and delivery to/from a consolidated inlet/outlet location at the boundary of the server 4500 without mixing with other air in the server 4500. Hence, the air which passes through the chip-level cooling device 2100 is segregated from the air which passes around the chip-level cooling device 2100 through the use of some physical barrier (e.g., a duct or manifold).

In type I, as shown in FIG. 58, there is no segregation and cooling air is provided directly to the heat sink without any intentional separation from the surrounding air. For example, an inlet duct 5706 connects the heat sink (e.g., the chip-level cooling device 2100) to an air delivery device (e.g., the fan 5702) that is open to the surrounding air inside the server 4500, which is, in this example, the cooling source. For example, see FIG. 49, which shows an inlet manifold 3364 providing cooling air to the inlet end 3398 of the impingement cooling device 3300. Similarly, outlet duct 5708 connects the chip-level cooling device 2100 to an exhaust fan 5704, which is also open to the surrounding air inside the server 4500, which is, in this case, the exhaust area. There is no segregation in this type I arrangement because the heated exhaust air can then be sucked back into the inlet duct 5706 by the fan 5702. In another example, a liner can be provided inside the server 4500 to prevent the heated exhaust air from being sucked back into the inlet duct 5706.

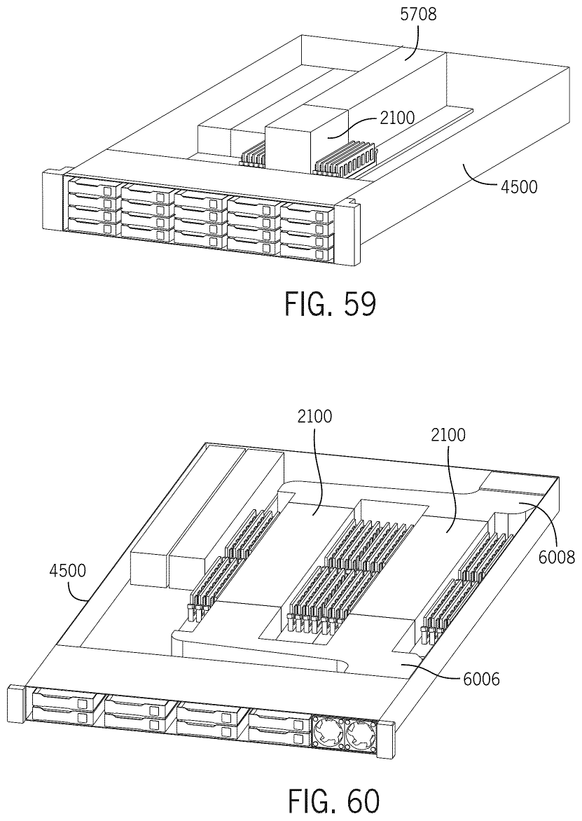

In type II, as shown in FIG. 59, either the fresh inlet air or the heated outlet air is ducted, but not both. In the latter type II configuration, air is sucked in from the cold aisle or room (the cooling source), through the heat sink (e.g., the chip-level cooling device 2100), to an outlet duct 5708 that can optionally send the air outside the boundary of the server 4500 (the exhaust area). There is half segregation because, while the relatively cool inlet air is that within the boundary of the server 4500, the heated exhaust air is delivered outside the boundary of the server 4500. In the former example, in which fresh inlet air is ducted, there is an inlet duct that pulls air in from outside the server boundary, while heated air is exhausted within the server boundary. Although a fan is not shown in the example of FIG. 59, it should be noted that a fan could be provided at the outlet end of or within the outlet duct 5708 (or at the inlet end of or within the inlet duct in the latter example of type II segregation).

In type III, as shown in FIG. 60, the inlet air and outlet air are both contained/ducted. An inlet manifold 6006 and an outlet manifold 6008 keep the air separated. Air outside of the server 4500 (the cooling source) is sucked into the system via the inlet manifold 6006, through the heat sinks (e.g., chip-level cooling devices 2100), and from there directed to an outlet manifold 6008, which can direct the air to a heat exchanger or send it outside (the exhaust area). Although not shown here, fans could be provided at the respective intake and outlet ends of the inlet and outlet manifolds 6006, 6008. Note there is full segregation because the intake air is brought in from outside the boundary of the server 4500 and the outlet air is exhausted outside the boundary of the server 4500.

Although the example of FIG. 60 includes two chip-level cooling devices 2100, type III segregation can be used for one, three, or more chip-level cooling devices 2100. Further, note that although only one chip-level cooling device 2100 is shown in the examples of FIGS. 58 and 59, two or more chip-level cooling devices 2100 could be cooled using type I or type II segregation. In general, then, the cooling system 2000 includes a server-level subsystem 2200 comprising one or more chip-level subsystems 2100.

Novel segregation methods include a duct or manifold for the inlet and outlet, such as for example shown in FIG. 60. This duct or manifold can be a rigid body or an inflatable/ribbed body that connects the air delivery to the heat sink or that connects the inlet/outlet rack manifolds to the heat sink. A liner in the server 4500 can act as the manifold, separating the cold air from the hot air. This liner divides the inlet and outlet of the heat sinks, so a tube connection is not needed. This liner may be a foam or a non-electrically conductive material such as a plastic insert. One or more tubes may be connected to the heat sink to duct air in and out. All of this air routing can also take place in the backplane of the server 4500, on one side of the server 4500, or through the top of the server 4500 when in 2U or more. All the CPUs may be positioned on one side or in the middle to reduce pressure drop and volume requirements. When the duct/manifold is connected from the top, it may converge and diverge as it connects to the heat sinks.

### 3.2. Filtration

Filtration may be built into the heat sink or the duct/manifold to remove particles over a particular size. This filtration system could be a metal or plastic mesh that keeps particles over a particular size from passing through, or a cyclonic type filter that separates particles from the air. The filter material could be further composed of fiber materials, electrostatic materials, pleated material arrangements, etc. The filter may be MERV rated or HEPA rated. A maintenance port could be built into the system that could be actuated automatically or manually to clean out the system. In the automatic case, the system health may be monitored to determine when maintenance is required. In either case, the fans could spin the opposite direction to clean out the system, or a pulse of compressed air may be sent through the device to clear dust or debris in the impingement cooling device, ducts/manifolds, and/or filter. The filter could optionally be removed for cleaning or replacement.

### 3.3. Air Delivery Methods

The air delivery device delivers air into and out of the server. The air delivery device on the server may contain a combination of push and pull air delivery for performance, efficiency and redundancy. There may be a plurality of air delivery devices upstream and/or downstream of the heat sink to provide redundant cooling if one air delivery device fails. The air delivery device(s) may be placed inside the server 4500 and may include a duct or manifold that connects to the heat sink. A venturi pump may also be used to multiply the airflow stream. The air delivery device may be connected directly to the heat sink as well. The air delivery devices may be placed at the front and/or rear of the server 4500 in case a hot swap is needed.

### 3.4. Connection Methods

The heat sink may be attached to the ducting system with a clip and latch system including a gasket between the duct and the heat sink, by being glued together, by a press fit, or by a press and twist connection into a protruding clip. There may be clamps on the server 4500 that attach to the rack manifold. The air delivery device may also be connected directly to the heat sink, e.g., via a duct. The impingement cooling device may contain hot swappable features to swap the plastic impingement piece while the server 4500 is running.

### 3.5. Sound Abatement

There are a number of sound abatement methods for reducing acoustic levels and vibrations to the server system, e.g. CPU, DIIM, clock, etc. Adjacent fans may be 180 degrees out of phase to reduce sound pressure levels. Sound insulation material may be lined around the ducts and/or fans to reduce vibrations and sound pressure levels from the air delivery device. A sound pressure wave may also be introduced, similar to noise canceling headphones, to eliminate some of the sound pressure.

Sound insulation material may be wrapped around the air delivery device to quiet the system. Mufflers may also be used in front and/or in back of the air delivery device or devices.

### 3.6. Controls

The system controls may be analog or digital to monitor the health of the chip-level cooling device 2100, clogging, system operation, or efficiency. The fan current may be monitored for various fan speeds, where a higher fan current for the same speed would mean the system is clogged. After this issue is identified, a maintenance light would illuminate, a message would be sent to the user, a clean-out cycle would turn on, and/or the server 4500 would shut down. Further system monitors include junction temperature and pressure/temperature sensors. If the junction temperature is outside the bounds for the specific heat sink, the same warning lights would illuminate. The pressure sensors would be upstream of the heat sink, and if there is a loss of pressure, warning lights would illuminate. The temperature sensor would be placed upstream and/or downstream of the heat sink. A high inlet temperature outside the spec of the server 4500 would illuminate warning lights. Too high of outlet temperature would illuminate the same warning lights, signaling a loss of air delivery. The system may be configured to adjust fan speed, turn on the maintenance light, shut down the server 4500, turn on a redundant blower and open a damper, shut down the server fans and turn on a rack fan, and/or run a blow-out cycle to maintain the temperature within a desired range.

Energy efficiency controls may be implemented into the system in communication with the server air delivery device and the rack/facility air delivery device. The rack/facility air delivery would represent the base load flow rate, operating at maximum efficiency, delivering the base load of air to the servers 4500. The fans in the server 4500 would represent further control over individual servers, operating at different speeds depending on the work load of the server 4500. This maximizes redundancy, performance and efficiency.

### 4. Rack-Level Sub System

The cooling system 2000 according to the present disclosure comprises a rack-level subsystem 2300 comprising one or more server-level subsystems 2200 and/or one or more chip-level subsystems 2100. The rack-level subsystem 2300 includes a manifold and optionally an air delivery device. This subsystem takes air from the facility level and delivers it to the servers 4500. The rack-level subsystem 2300 then returns the air back to the facility level, creating a complete separation of environments from the server air and the room air.

An exemplary rack-level subsystem 2300 is shown in FIG. 61, where the inlet manifold 6102 delivers cooling fluid to each of the servers 4500, which are stacked one on top of the other on a rack 6110. After passing through the server-level subsystem(s) 2200 and heat sink within one or more of the servers 4500, the fluid exits through the outlet manifold 6104 on the back. The outlet manifold 6104 allows for alternative flow paths, improving redundancy and reliability. The fluid leaves through the top 6106 of the outlet manifold 6104 to the facility-level subsystem 2400 (not shown here). This rack-level sub system 2300 can be a repeating unit cell in the greater system.

### 4.1. Flow Segregation and Manifold Placement

The inlet manifold 6102 and outlet manifold 6104 contain at least one wall 6103, 6105 separating the fluid inside of the manifold 6102, 6104 from the room environment. In some examples, there may only be an outlet manifold 6104, in which case the inlet air is taken in from the cold aisle. This one-sided manifolding arrangement may reduce the overall system pressure drop and improve efficiency. The manifolds 6102, 6104 could be plastic, 3D-printed material, metal, or other known materials. Pieces of the manifold could be attached or bonded together, or each manifold 6102, 6104 could be a single piece. A bag-style manifold may be used, which may contain a ribbed structure to keep it from collapsing. The manifold 6012, 6104 may be set up adjacent to or inside of the rack 6110 to deliver air from the facility to the servers 4500 and vice versa. Nontrivial shapes (e.g., modified pentagon) for the manifold 6012, 6104 may be used to increase cross-sectional area and reduce pressure drop. The inlet manifold 6102 may converge towards the servers furthest from the source of cool air and the outlet manifold 6104 may diverge towards the facility-level manifold to improve flow uniformity and reduce pressure drop. The manifold 6102, 6104 may have features that allow air to pass transversely through the manifold 6102, 6104, which may otherwise occlude the face of the servers 4500.

### 4.2. Manifold Mounting Methods

The manifold 6102, 6104 may be integrated into the rack 6110, bolted onto the rack 6110, or clamped onto the rack 6110. In one embodiment, the manifold 6102, 6104 may be mobile, e.g. wheeled up, slidable, and easy to remove. When the manifold 6102, 6104 is clamped/fastened on or integrated into the rack 6110, this results in high reliability for consistently delivering the airflow to the servers 4500. A hinge may be located on the edge of the rack 6110 so that the manifold 6102, 6104 may swing open like a door when a server 4500 needs to be taken out or put in.

### 4.3. Cap for Unused Connections when a Slot is not in Use

As shown by the detailed view in FIG. 61, the manifold 6102, 6104 may be segregated into sections by way of internal walls 6108, creating ports 6112 leading to individual servers 4500 or a group of servers 4500. When a portion of the manifold 6102, 6104 is not in use, caps may be attached onto the ends of the ports 6112, covering the ports 6112 and sealing them off from the inlet flow of cool air. The cap 6114 may be attached over the port 6112 using latches or clamps 6116, as shown in FIG. 62. A gasket 6118 can be used to seal the cap 6114 over the end of the port 6112. The cap 6114 may be made of sheet metal, may be injection molded, or may be 3D printed with the gasket 6118 and clamps 6116. The cap may instead be a foam insert 6120 as shown in FIG. 63. When foam inserts 6120 are used, a lip inside the port 6112 may be used so the foam inserts 6120 don't fall inside the manifold 6102, 6104. A false bottom on the manifold 6102, 6104 may also be added to collect fallen objects inside the manifold 6102, 6104. A groove may also be built into the manifold 6102, 6104 to receive sliding covers over the open ends of the ports 6112, blocking airflow therethrough. These port covers may also be built into the manifold 6102, 6104. Similar covers may be provided for ports in the outlet manifold 6104.

### 4.4. Connection Methods: Rack—Server

Connections between the rack-level manifolds 6102, 6104 and server-level manifolds 6006, 6008 (FIG. 60) may contain a number of features for maintenance and reliably securing the connections. A clamp-style system may be used such as shown in FIG. 62, or the clamp may attach in, for example, five-server increments instead of requiring attachment to a port 6112 for each individual server 4500. For example, the downstream end of an inlet port 6112 may be clamped to five separate inlet manifolds 6006 on five separate servers 4500. These connections may also be made by way of a flexible ribbed tube or a tube that turns (e.g., quarter turn) to seal.

### 4.5. Air Delivery Methods

As shown in FIGS. 61 and 64, a rack-level air delivery device 6122 may be integrated into a portion of the outlet manifold 6104. Although not shown here, an air delivery device could alternatively or additionally be integrated into the inlet manifold 6102. Redundancy may be achieved by adding ducts 6124 to connect a plurality of outlet manifolds 6104 together and thereby provide a redundant path. (The same could be done for the inlet manifolds 6102, although not shown here.) This redundant flow path also serves as a key maintenance feature allowing the flow to go through different locations while one flow path is being serviced. Further maintenance ports may be added to the system to blow in compressed air to clean out the system (manually or automatically). An additional air delivery device may be attached to the manifold connections, creating redundancy in the system if one air delivery device fails. A solenoid or actuator can connect to a sensor on each outlet, detecting a loss of flow. Upon loss of flow detection, a baffle may be opened to allow the redundant blower to supplement cooling while the failed blower is replaced. A baffle may also be closed to the failed blower, such that air does not come in through this connection to the redundant blower.

The rack-level subsystem 2300 could be installed in a pressurized room (e.g., at 2-3 Bar). This could increase air density and dramatically reduce the pumping power in the room, thereby improving cooling performance. Further, limitations of air delivery methods are greatly reduced by the devices moving more mass flow rate in a higher density environment.

### 4.6. Sound and or Better Thermal Performance

Insulation may be attached to the manifold 6102, 6104 to thermally and/or acoustically separate it from the room environment. This will prevent heat from the server outlet air increasing the temperature of the air in the room. This may also isolate and suppress vibrations.

### 4.7. Controls

Several control features may be added to improve reliability and maintenance of the ducting system. A control panel may be attached to the manifold 6102, 6104 to provide relevant information including control options, system health, and current operating conditions. This control panel may display chip temperature limits, efficiency targets, or the ability to manually set the base load for the rack-or facility-level air delivery. (The base load here means a minimum airflow rate for the rack system.) Fan speed can be adjusted to achieve a target temperature at the chip level. For example, a controller can adjust fan speed at the server level, at the rack level, at the facility level, or at some combination of levels to achieve a particular chip temperature. Weather forecasts may be communicated to the control system to predict efficiencies and prepare the system for the best operating points on a daily or weekly basis. An airflow sensor such as a pitot tube may be attached to the inlet or outlet duct of the system to serve as the communication between the servers and the rack/facility-level air delivery systems. An inflatable bag indicator may also be attached to the manifold 6102, 6104 to indicate a loss of flow.

### 5. Facility-Level Sub System

The cooling system 2000 of the present disclosure comprises a facility-level subsystem 2400 comprising one or more rack-level subsystems 2300 and/or one or more server-level subsystems 2200 and/or one or more chip-level subsystems 2100. The facility-level subsystem 2400 is responsible for moving the air from a central location (e.g., outside or RDU (rack distribution unit)), to the servers 4500, and back to a central location (e.g., outside or RDU). There are a number of innovative features to this subsystem to provide redundancy, filtration, efficiency improvements, and safety features.

A schematic of one example of a facility-level subsystem 2400 is shown in FIG. 65, where the goal is to deliver cool inlet fluid (as shown by arrows 6502) to the rack-level subsystems 2300 and remove heated outlet fluid (as shown by arrows 6504) from the rack-level subsystems 2300 after it has been used to cool the servers 4500. In one embodiment, the air would be supplied from outside to each server rack and exhausted back outside. This embodiment allows for the complete bypass and elimination of air conditioning or other secondary heat exchange steps. The air could be filtered, conditioned, cooled, heated, or otherwise treated at various points throughout the facility-level subsystem 2400. In a second embodiment, the air could be maintained within a closed-loop system. Rather than being exhausted outside, the air could be routed to a secondary cooling system (i.e., a heat exchanger), where the heat could be removed from the air stream and transferred into the secondary cooling loop (e.g., liquid cooling coil, radiator, evaporator or similar device). The secondary cooling loop would transfer the heat outside for removal via a cooling tower, condenser, radiator, evaporative cooling tower, chiller, or similar device. In the case where the secondary cooling loop comprises a vapor compression cooling system, it could be configured as a very high efficiency, “low-lift” system. In this configuration, the secondary cooling loop would only reduce the air temperature slightly (low-lift) which allows for greater maximum (Carnot) cooling efficiencies to be achieved. Such a low-lift system would be made possible by the improved chip-level and rack-level subsystems, which would be capable of sufficiently removing heat from sever components (e.g., via RJI and TJI technologies) using higher temperature inlet air.

### 5.1. Flow Segregation Methods

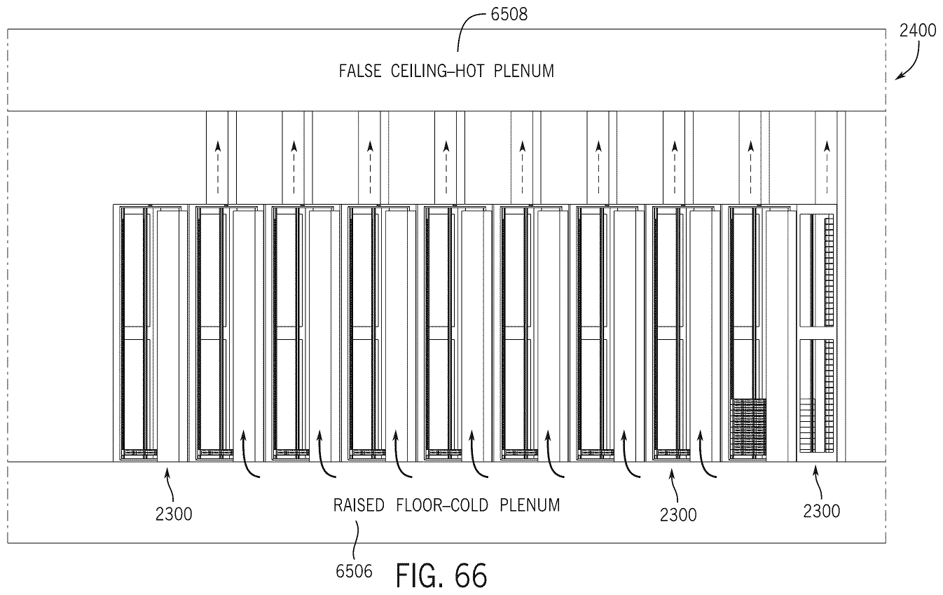

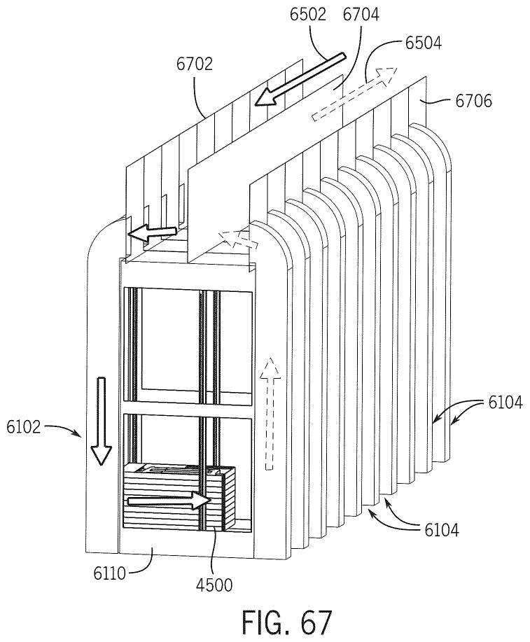

As shown in FIG. 66, the inlet fluid 6502 and outlet fluid 6504 may be separated from the surrounding room environment with a cold plenum 6506 under a raised floor and a hot plenum 6508 above a false ceiling. This requires minimum modifications to the facility, retrofitting the existing infrastructure to accommodate higher rack densities or to provide better efficiencies. Novel connections between the facility and rack will be discussed in the next section. This may also be done with a central inlet grate for a room and only a single outlet manifolding system. By eliminating the inlet manifold, the pressure drop is nominally cut in half. Another segregation method involves air segregation on top of the racks 6110 as shown in FIG. 67. Three vertical liners 6702, 6704, 6706 separate the cool fluid 6502 and hot fluid 6504 from the greater room environment, as each liner 6702, 6704, 6706 would extend from the racks 6110 to the ceiling of the room. A horizontal liner (not shown) may also be used between the racks 6110 and the liners 6702, 6704, 6706, in which at least the middle liner 6704 seals to the horizontal liner over the racks 6110. This horizontal liner may be an inflatable bag with ribs or it may be a sheet metal duct. One end of each liner 6702, 6704, 6706 would connect to an inlet of ambient air and the other end of each liner 6702, 6704, 6706 would connect to an outlet for the return air. Further, a horizontal liner could be used above the liners 6702, 6704, 6706 as well.

### 5.2. Connection Methods: Room—Rack

The connections between the rack and facility manifolds can contain several features to securely mate these two bodies. The inlet manifold may be integrated with a floor tile using a gasket and clamping clips. The tile is specifically designed for the rack manifold. The connection may also be a turn seal. The outlet side may be integrated with the ceiling, using similar clamping mechanisms. The outlet manifold may diverge as it approaches the ceiling to increase cross sectional flow area.

### 5.3. Air Delivery Methods

Facility-level air delivery may be at the inlet, outlet, or a combination of these to provide the necessary flow rates for cooling. In other examples, there may be no facility-level air delivery in the system. The air may be transported through the facility-level subsystem 2400 using one or more facility-level air delivery devices (e.g. fan, blower, venturi pump). Alternatively, there may be no facility-level air delivery devices, and the air could instead be transported using air delivery devices at the chip level, the server level, the rack level, or at any combination of these various levels. Preferably, there are air delivery device(s) in at least one of the four subsystem levels (chip level, server level, rack level, and/or facility level). Optionally, all subsystem levels or any combination of subsystem levels may contain air delivery devices. For example, in one embodiment, the system could comprise chip-level fans and rack-level blowers, but no air delivery devices at the server level or the facility level. In another embodiment, the system could comprise server-level venturi pumps and one or more facility-level axial fans, but no air delivery devices at the chip level or rack level. In another embodiment, chip-level fans, server-level fans, rack-level blowers, and facility-level fans could all be included in the system. Partial implementation could be performed at each level as well. For example, in one embodiment, some chip-level subsystems (but not all) on a server 4500 may have fans attached, and some servers 4500 (but not all) may have fans attached, and some racks 6110 (but not all) may have fans attached.

Generally, implementing air delivery devices at lower levels (where chip-level is the lowest level subsystem) has the benefit of improving system controllability, while implementing air delivery devices at higher levels (where facility-level is the highest level subsystem) has the benefit of improving airflow efficiency. For example, if all chips have chip-level air delivery, then airflow could be individually optimized to every chip in the complete data center system to ensure that each receives optimal cooling (utilizing enough air to maintain a setpoint temperature, but not so much as to cool the chip more than is necessary). This would also allow for rapid changes in airflow to individual components based on local changes in operation (e.g., changes in computational load, changes in ambient conditions). Air delivery devices at the server level would allow for precision optimized air delivery for each server 4500 in the system. By contrast, it is generally true that larger air delivery devices can be fabricated with greater efficiency at lower cost per airflow than smaller devices. For this reason, inclusion of higher-level air delivery devices can allow for improved airflow efficiency. Adding fans at all levels will increase component costs, while limiting the number of air delivery devices will reduce costs. This adds another element of optimization which could be done accounting for financial benefits.

In one preferred embodiment, airflow delivery devices (e.g., fans) could be included at all four subsystem levels and may operate cooperatively in a multi-level integrated control system to provide optimized airflow throughout the system. In this embodiment, fans in the facility-level subsystem 2400 would provide some baseline airflow to every rack 6110 in the system (enough to cool some baseline heat load from each rack 6110, but not so much that any equipment is being “over-cooled” by it). Blowers integrated into each rack-level subsystem 2300 would provide additional airflow to those racks 6110 that need it. For example, there may be ten racks 6110 in a system, each operating at varying power loads between 10 and 50 kW per rack. Blowers on the 10 kW racks may not be turned on or may not be present at all, while the 50 kW racks will have blowers operating at high speed. Other racks (e.g., 25 kW racks) may have blowers running at reduced speeds. All rack-level blowers could be dynamically controlled to meet the needs of the computational load applied to each. Further, within the rack level, the rack blower may provide a baseline air delivery to all servers 4500 in a rack 6110 with additional airflow provided as needed to each individual server 4500 by way of fans implemented as part of the server-level subsystems 2200. Similar to the facility level, each server 4500 in a rack 6110 may operate at a varying heat load (e.g., from 300 W to 3 kW). Server-level fans in the 300 W servers 4500 may be turned off or may not be present, while fans in the 3 kW servers 4500 may be operating at high speeds. The same concept may be implemented at the chip level for the chip-level subsystem 2100.

Sound insulation material may be wrapped around any air delivery device(s) to reduce the sound pressure level of the air delivery device(s). A muffler, such as a circular dissipative silencer, may also be used before and/or after the air delivery device(s).

### 5.4. Inlet Stream Air Handling

The inlet air to the facility or rack manifold may be treated a number of ways to improve efficiency, reliability, or ease of installation. To improve efficiency and reduce peak loads, a PCM (phase change material) may be charged during the night or hours of excess power and discharged during the peak load or highest temperature of the day. Alternative to the PCM, a compressed air energy storage system may be used. Air is compressed into a storage tank during the same hours and discharged during the same hours. When the compressed air is discharged, due to the ideal gas law, a cooling effect is achieved as it expands. Another method for thermally treating the inlet air is spraying water into the system, where a cooling effect is achieved from the evaporation of water into the air. Finally, a heat exchanger may be used at the inlet coupled to a chiller, economizer, or cooling tower to lower the inlet air temperature during peak hours and maximize system efficiency.

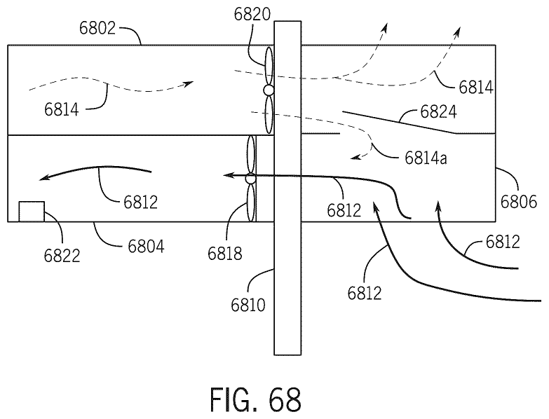

Alternatively, during the winter months the ambient air may be too cold to directly allow into the facility for cooling. Hot outlet air may be recirculated in these scenarios to allow the average inlet air temperature to be above the minimum as shown in FIG. 68. In this system, an exhaust duct 6802 is coupled to a supply duct 6804 by way of an air-handling unit (AHU) 6806. The exhaust duct 6802 and supply duct 6804 are inside a building, while the AHU 6806 is outside the building, as shown by the wall 6810. The AHU 6806 includes an inlet grate for intaking cool air 6812 and an outlet grate for exhausting hot air 6814. An intake fan 6818 blows cool air 6812 into the supply duct 6804, which is then routed to the facility-level subsystem 2400. An exhaust fan 6820 pulls hot air 6814 out of the exhaust duct 6802 and into the AHU 6806. A temperature sensor 6822 is located in the supply duct 6804. The temperature sensor 6822 is in communication with a controller (not shown) that controls movement of a baffle 6824 in the AHU 6808, which baffle 6824 separates the inlet and outlet grates. The baffle 6824 may be normally closed. When the temperature of the cool air 6812 (as determined by the temperature sensor 6822) drops below a predetermined threshold, the controller opens the baffle 6824, as shown by the position in FIG. 68, to allow a portion 6814a of the hot air 6814 to mix with the cool air 6812. This warmer air is then provided into the supply duct 6804. The controller keeps the baffle 6824 open until the temperature of the air in the supply duct 6804 (as determined by the temperature sensor 6822) is above a predetermined threshold.

The air delivery devices for the facility-, rack-, server- and chip-level subsystems may be inside a larger system such as a pressurized container that could take the shape of an iglu, cylinder, or other pressure-worthy shape to increase the air density. This system may sit in a media with high heat transfer such as a windy pathway where it is naturally cooled by convection or in a body of water where it can dissipate heat through conduction and convection. This body may also be placed underground where it can dissipate heat through conduction. The pressure ratios on fans are limited in ambient conditions; by increasing the air density inside one of the four subsystems, the same volumetric flow rate provides significantly higher mass flow rates and can thus absorb more energy per volume. The same can be said about other air delivery devices such as blowers. This system dramatically lowers flow work to drive the media and results in a very high efficiency system.

### 5.5. Filtration

The inlet air stream may need to be filtered, and there are several methods for removing particles above a certain size. Using a MERV filter is the most common, where a filter bank would be made of the MERV 1-15 filters. Alternatively or additionally, a mesh wire may be used to filter down to a bigger size that the MERV filters do. This enhances ease of maintenance allowing these larger filters to be cleaned with compressed air. A cyclonic filter may also be used at the inlet using the centrifugal force to remove the particles.

### 5.6. Outlet Stream Air Handling

The outlet air that is leaving at elevated temperatures may also be handled a few ways to comply with regulations and/or use the waste heat for useful purposes. Relevant regulations that may need to be followed could include limiting the discharge temperature into the ambient environment. When this is necessary, an intercooler or radiator could be attached to the outlet, lowering the discharge temperature. A fan could also be used to mix the outlet air with ambient air. A waste heat recovery attachment could also be made useful. The outlet air stream may be attached to the facilities to provide cooling thereto. The outlet air stream may also be used for district heating. The air may be passed through a radiator, heating water or some liquid to transport the energy more efficiently. Finally, a CO₂ removal system may also be attached to the facility to use the heated air energy to remove CO₂ from the atmosphere. This could be done by using a solid sorbent direct air capture system. A small amount of additional energy may be added to this heated air to drive a chemical reaction to remove the carbon.

### 5.7. Controls

Facility controls can improve reliability through diagnostics and actuator systems. Detecting loss of flow is key to identifying issues. Attaching a pressure sensor to a 3D printed pitot tube may be used to monitor volumetric flow rate. This pitot tube may be at the inlet after the filter or at some point downstream in the system. Upon detection, a low flow sensor would illuminate, identifying the system needs maintenance. This may also be done with pressure or temperature sensors, identifying extremes of these variables. If the pressure is too low, or similarly if the temperature is too high, this will indicate a loss of flow.

### 5.8. Software Tools

Software tools may also be developed for data center design and optimization to minimize power consumption of the server fans and air delivery systems. These tools may be used to quickly size ducts/manifolds required for a target rack heat load.

The tool may have features that allow a user to create redundancy, select a control system, and pick maintenance cycles.

### 6. Examples of the Present Disclosure

A number of embodiments of the present disclosure have been described. While this specification contains many specific implementation details, these should not be construed as limitations on the scope of any disclosures or of what may be claimed, but rather as descriptions of features specific to particular embodiments of the present disclosure.

Those having ordinary skill in the art will appreciate that examples provided herein can be combined in various ways with other examples. That is, the port-scale protrusions and/or the micro-scale protrusions providing area enhancement (FIGS. 25, 27-29, and 31) can be combined with the converging inlet channels and diverging outlet channels (FIGS. 32-44). Examples in which multiple impingement target plates are stacked one on top of the other (FIGS. 55 and 56) or aligned next to each other (FIGS. 51 and 52) can be combined with port-scale area enhancement and/or micro-scale area enhancement as well. The concepts of different shapes and relative arrangements of injection ports and extraction ports (FIGS. 15-24) can be combined with any of the port-scale area enhancement and/or micro-scale area enhancement (FIGS. 25, 27-29, and 31) and/or the stacked or aligned impingement target plates (FIGS. 51, 52, 55, and 56) and/or the converging inlet channels and diverging outlet channels (FIGS. 32-44). Those having ordinary skill in the art will understand that these are merely exemplary combinations, and many more combinations are possible.

Example 1. An impingement cooling device comprising:
a distributor plate including an upstream side, a downstream side opposite the upstream side, and a plurality of injection ports extending through the distributor plate from the upstream side to the downstream side; and
an impingement target plate including an upstream side, a downstream side opposite the upstream side, and a plurality of extraction ports extending through the impingement target plate from the upstream side to the downstream side;
wherein the plurality of injection ports are configured to accelerate a cooling fluid as the cooling fluid passes therethrough from the upstream side to the downstream side of the distributor plate;
wherein the impingement target plate is arranged adjacent the distributor plate such that the accelerated cooling fluid is directed onto the upstream side of the impingement target plate and thereafter through the extraction ports to the downstream side of the impingement target plate; and
wherein the upstream side of the impingement target plate and/or at least one extraction port in the plurality of extraction ports is provided with a plurality of protrusions configured to increase a conductive surface area of the upstream side of the impingement target plate and/or a conductive surface area within the at least one extraction port in the plurality of extraction ports, respectively.

Example 2. The impingement cooling device of example 1, wherein a subset of protrusions in the plurality of protrusions on the upstream side of the impingement target plate and/or in the at least one extraction port have micro-scale dimensions.

Example 3. The impingement cooling device of example 2, wherein the micro-scale protrusions on the upstream side of the impingement target plate are elliptical in cross section.

Example 4. The impingement cooling device of example 3, wherein a subset of the micro-scale protrusions on the upstream side of the impingement target plate each have a major axis that is aligned radially with respect to a given extraction port in the plurality of extraction ports.

Example 5. The impingement cooling device of example 3 or example 4, wherein the micro-scale protrusions on the upstream side of the impingement target plate project from the upstream side of the impingement target plate at various heights.

Example 6. The impingement cooling device of example 5, wherein the injection ports have outlets on the downstream side of the distributor plate;
wherein the extraction ports have inlets on the upstream side of the impingement target plate; and
wherein the height of the micro-scale protrusions on the upstream side of the impingement target plate closest to the outlet of a given injection port in the plurality of injection ports is less than the height of the micro-scale protrusions on the upstream side of the impingement target plate closest to the inlet of a given extraction port in the plurality of extraction ports.

Example 7. The impingement cooling device of any of examples 1-6, wherein the injection ports have outlets on the downstream side of the distributor plate;
wherein a subset of protrusions in the plurality of protrusions on the upstream side of the impingement target plate have port-scale dimensions similar to dimensions of the injection and extraction ports; and
wherein the port-scale protrusions on the upstream side of the impingement target plate are arranged about areas immediately opposite the outlets of respective injection ports in the plurality of injection ports such that the accelerated cooling fluid is directed onto the areas surrounded by the port-scale protrusions and then around the port-scale protrusions prior to being directed through the extraction ports.

Example 8. The impingement cooling device of example 7, wherein the port-scale protrusions have a curved diamond shape in cross section.

Example 9. The impingement cooling device of example 7, wherein a given extraction port is defined along first and second axes that are perpendicular to one another;
wherein a major axis of a first port-scale protrusion is aligned with the first axis of the given extraction port;
wherein a major axis of a second port-scale protrusion is aligned with the second axis of the given extraction port; and
wherein an elliptical flow path is defined between the first and second port-scale protrusions.

Example 10. The impingement cooling device of example 9, wherein micro-scale protrusions are formed within the elliptical flow path on the upstream side of the impingement target plate.

Example 11. The impingement cooling device of any of examples 1-10, wherein a lip is provided on the downstream side of the impingement target plate adjacent an outlet of at least one extraction port in the plurality of extraction ports.

Example 12. The impingement cooling device of any of examples 1-11, further comprising a baseplate, wherein the distributor plate and the impingement target plate are coupled to and project perpendicularly with respect to the baseplate.

Example 13. The impingement cooling device of example 12, wherein the baseplate comprises a vapor chamber or a heat pipe.

Example 14. The impingement cooling device of example 12 or example 13, wherein the baseplate is configured to be situated over an object to be cooled.

Example 15. The impingement cooling device of example 14, wherein the object to be cooled is an integrated circuit.

Example 16. The impingement cooling device of any of examples 12-15, wherein the distributor plate is a first distributor plate and the impingement target is a first impingement target plate, and further comprising:
a second distributor plate coupled to and projecting perpendicularly with respect to the baseplate, the second distributor plate including an upstream side, a downstream side opposite the upstream side, and a plurality of injection ports extending through the second distributor plate from the upstream side to the downstream side and configured to accelerate the cooling fluid as the cooling fluid passes therethrough from the upstream side to the downstream side of the second distributor plate; and
a second impingement target plate coupled to and projecting perpendicularly with respect to the baseplate, the second impingement target plate including an upstream side, a downstream side opposite the upstream side, and a plurality of extraction ports extending through the second impingement target plate from the upstream side to the downstream side;
wherein the second impingement target plate is arranged adjacent the second distributor plate such that the accelerated cooling fluid is directed onto the upstream side of the second impingement target plate and thereafter through the extraction ports to the downstream side of the second impingement target plate;
wherein the first and second impingement target plates are arranged laterally beside one another with the downstream side of the first impingement target plate opposing the downstream side of the second impingement target plate so as to form an outlet channel therebetween.

Example 17. The impingement cooling device of example 16, further comprising conductive material spanning the outlet channel between the downstream side of the first impingement target plate and the downstream side of the second impingement target plate.

Example 18. The impingement cooling device of example 17, wherein the conductive material is formed as one or more of the following: cylindrical posts, rectangular fins, louver fins, metallic foam, and spun-like web material.

Example 19. The impingement cooling device of any of example 16-18, wherein the baseplate and the outlet channel extend in a longitudinal direction, and wherein the outlet channel varies in lateral width along the longitudinal direction.

Example 20. The impingement cooling device of any of examples 16-19, further comprising:
a third distributor plate coupled to and projecting perpendicularly with respect to the baseplate, the third distributor plate including an upstream side, a downstream side opposite the upstream side, and a plurality of injection ports extending through the third distributor plate from the upstream side to the downstream side and configured to accelerate the cooling fluid as the cooling fluid passes therethrough from the upstream side to the downstream side of the third distributor plate; and
a third impingement target plate coupled to and projecting perpendicularly with respect to the baseplate, the third impingement target plate including an upstream side, a downstream side opposite the upstream side, and a plurality of extraction ports extending through the third impingement target plate from the upstream side to the downstream side;
wherein the third impingement target plate is arranged adjacent the third distributor plate such that the accelerated cooling fluid is directed onto the upstream side of the third impingement target plate and thereafter through the extraction ports to the downstream side of the third impingement target plate; and
wherein the second and third distributor plates are arranged laterally beside one another with the upstream side of the second distributor plate opposing the upstream side of the third distributor plate so as to form an inlet channel therebetween.

Example 21. The impingement cooling device of example 20, further comprising an inlet manifold coupled to the inlet channel and an outlet manifold coupled to the outlet channel;
wherein the inlet manifold is configured to provide the cooling fluid from a cooling fluid source to the inlet channel; and
wherein the outlet manifold is configured to provide the cooling fluid from the outlet channel to an exhaust area.

Example 22. An impingement cooling device comprising:
a first distributor plate including an upstream side, a downstream side opposite the upstream side, and a first plurality of injection ports extending through the first distributor plate from the upstream side to the downstream side and configured to accelerate a cooling fluid as the cooling fluid passes therethrough from the upstream side to the downstream side of the first distributor plate;
a first impingement target plate including an upstream side, a downstream side opposite the upstream side, and a first plurality of extraction ports extending through the first impingement target plate from the upstream side to the downstream side;
a second distributor plate including an upstream side, a downstream side opposite the upstream side, and a second plurality of injection ports extending through the second distributor plate from the upstream side to the downstream side and configured to accelerate the cooling fluid as the cooling fluid passes therethrough from the upstream side to the downstream side of the second distributor plate;
a second impingement target plate including an upstream side, a downstream side opposite the upstream side, and a second plurality of extraction ports extending through the second impingement target plate from the upstream side to the downstream side;
wherein the first impingement target plate is arranged adjacent the first distributor plate such that the accelerated cooling fluid is directed onto the upstream side of the first impingement target plate and thereafter through the first plurality of extraction ports to the downstream side of the first impingement target plate;
wherein the second impingement target plate is arranged adjacent the second distributor plate such that the accelerated cooling fluid is directed onto the upstream side of the second impingement target plate and thereafter through the second plurality of extraction ports to the downstream side of the second impingement target plate; and
wherein the first distributor plate is non-parallel with the second distributor plate and/or the first impingement target plate is non-parallel with the second impingement target plate.

Example 23. The impingement cooling device of example 22, wherein the first and second impingement target plates are arranged laterally beside one another with the downstream side of the first impingement target plate opposing the downstream side of the second impingement target plate so as to form an outlet channel therebetween.

Example 24. The impingement cooling device of example 23, further comprising:
a third distributor plate including an upstream side, a downstream side opposite the upstream side, and a third plurality of injection ports extending through the third distributor plate from the upstream side to the downstream side and configured so as to accelerate the cooling fluid as the cooling fluid passes therethrough from the upstream side to the downstream side of the third distributor plate; and
a third impingement target plate including an upstream side, a downstream side opposite the upstream side, and a third plurality of extraction ports extending through the third impingement target plate from the upstream side to the downstream side;
wherein the third impingement target plate is arranged adjacent the third distributor plate such that the accelerated cooling fluid is directed onto the upstream side of the third impingement target plate and thereafter through the third plurality of extraction ports to the downstream side of the third impingement target plate; and
wherein the second and third distributor plates are arranged laterally beside one another with the upstream side of the second distributor plate opposing the upstream side of the third distributor plate so as to form an inlet channel therebetween.

Example 25. The impingement cooling device of example 24, wherein the inlet channel is configured to receive the cooling fluid via an inlet end of the impingement cooling device;
wherein the outlet channel is configured to direct the cooling fluid to an outlet end of the impingement cooling device;
wherein the inlet channel has a width that decreases from the inlet end toward the outlet end of the impingement cooling device; and
wherein the outlet channel has a width that increases from the inlet end toward the outlet end of the impingement cooling device.

Example 26. The impingement cooling device of example 24, further comprising a plurality of pairs of distributor plates and impingement target plates arranged so as to create a plurality of inlet channels and a plurality of outlet channels.

Example 27. The impingement cooling device of example 26, wherein the plurality of inlet channels are configured to receive the cooling fluid via an inlet end of the impingement cooling device;
wherein the plurality of outlet channels are configured to direct the cooling fluid to an outlet end of the impingement cooling device;
wherein each inlet channel in the plurality of inlet channels has a width that decreases from the inlet end toward the outlet end of the impingement cooling device; and
wherein each outlet channel in the plurality of outlet channels has a width that increases from the inlet end toward the outlet end of the impingement cooling device.

Example 28. The impingement cooling device of example 27, further comprising:
an inlet manifold coupled to each inlet channel in the plurality of inlet channels; and
an outlet manifold coupled to each outlet channel in the plurality of outlet channels;
wherein the inlet manifold is configured to provide the cooling fluid from a cooling fluid source to the plurality of inlet channels; and
wherein the outlet manifold is configured to provide the cooling fluid from the plurality of outlet channels to an exhaust area.

Example 29. The impingement cooling device of any of examples 22-28, wherein the upstream side of the first impingement target plate and/or at least one extraction port in the first plurality of extraction ports is provided with a plurality of protrusions configured to increase a conductive surface area of the upstream side of the first impingement target plate and/or a conductive surface area within the at least one extraction port in the first plurality of extraction ports, respectively.

Example 30. The impingement cooling device of example 29, wherein a subset of protrusions in the plurality of protrusions on the upstream side of the first impingement target plate and/or in the at least one extraction port have micro-scale dimensions.

Example 31. The impingement cooling device of example 30, wherein the micro-scale protrusions on the upstream side of the first impingement target plate are elliptical in cross section.

Example 32. The impingement cooling device of example 31, wherein a subset of the micro-scale protrusions on the upstream side of the first impingement target plate each have a major axis that is aligned radially with respect to a given extraction port in the first plurality of extraction ports.

Example 33. The impingement cooling device of example 31 or example 32, wherein the micro-scale protrusions on the upstream side of the first impingement target plate project from the upstream side of the first impingement target plate at various heights.

Example 34. The impingement cooling device of example 33, wherein the injection ports in the first plurality of injection ports have outlets on the downstream side of the first distributor plate;
wherein the extraction ports in the first plurality of extraction ports have inlets on the upstream side of the first impingement target plate;
wherein the height of the micro-scale protrusions on the upstream side of the first impingement target plate closest to the outlet of a given injection port in the first plurality of injection ports is less than the height of the micro-scale protrusions on the upstream side of the first impingement target plate closest to the inlet of a given extraction port in the first plurality of extraction ports.

Example 35. The impingement cooling device of any of examples 29-34, wherein the injection ports in the first plurality of injection ports have outlets on the downstream side of the first distributor plate;
wherein a subset of protrusions in the plurality of protrusions on the upstream side of the first impingement target plate have port-scale dimensions similar to dimensions of the injection ports in the first plurality of injection ports and the extraction ports in the first plurality of extraction ports; and
wherein the port-scale protrusions are arranged about areas immediately opposite the outlets of respective injection ports in the first plurality of injection ports such that the accelerated cooling fluid is directed onto the areas surrounded by the port-scale protrusions and then around the port-scale protrusions prior to being directed through the extraction ports.

Example 36. The impingement cooling device of example 35, wherein the port-scale protrusions have a curved diamond shape in cross section.

Example 37. The impingement cooling device of example 36, wherein a given extraction port in the first plurality of extraction ports is defined along first and second axes that are perpendicular to one another;
wherein a major axis of a first port-scale protrusion is aligned with the first axis of the given extraction port; and
wherein a major axis of a second port-scale protrusion is aligned with the second axis of the given extraction port; and
wherein an elliptical flow path is defined between the first and second port-scale protrusions.

Example 38. The impingement cooling device of example 37, wherein micro-scale protrusions are formed within the elliptical flow path on the upstream side of the first impingement target plate.

Example 39. The impingement cooling device of any of examples 22-38, wherein a lip is provided on the downstream side of the first impingement target plate adjacent an outlet of at least one extraction port in the first plurality of extraction ports.

Example 40. The impingement cooling device of any of examples 22-39, further comprising a baseplate, wherein the first and second distributor plates and the first and second impingement target plates are coupled to and project perpendicularly with respect to the baseplate.

Example 41. The impingement cooling device of example 40, wherein the baseplate comprises a vapor chamber or a heat pipe.

Example 42. The impingement cooling device of example 40 or example 41, wherein the baseplate is configured to be situated over an object to be cooled.

Example 43. The impingement cooling device of example 42, wherein the object to be cooled is an integrated circuit.

Example 44. An impingement cooling device comprising:
a first plate including an upstream side, a downstream side opposite the upstream side, and a first plurality of ports extending through the first plate from the upstream side to the downstream side and configured to accelerate a cooling fluid as the cooling fluid passes therethrough from the upstream side to the downstream side of the first plate; and
a second plate including an upstream side, a downstream side opposite the upstream side, and a second plurality of ports extending through the second plate from the upstream side to the downstream side and configured to accelerate the cooling fluid as the cooling fluid passes therethrough from the upstream side to the downstream side of the second plate;
wherein the first plate is arranged adjacent the second plate such that the accelerated cooling fluid from the first plurality of ports is directed onto the downstream side of the second plate and such that accelerated cooling fluid from the second plurality of ports is directed onto the downstream side of the first plate; and
wherein the first plate is non-parallel with the second plate.

Example 45. A cooling system comprising the impingement cooling device of any of examples 1-44, wherein the impingement cooling device is a chip-level subsystem configured to cool an integrated circuit.

Example 46. A cooling system comprising a server-level subsystem comprising one or more chip-level subsystems according to example 45.

Example 47. A cooling system comprising a rack-level subsystem comprising one or more server-level subsystems according to example 46 and/or one or more chip-level subsystems according to example 45.

Example 48. A cooling system comprising a facility-level subsystem comprising one or more rack-level subsystems according to example 47 and/or one or more server-level subsystems according to example 46 and/or one or more chip-level subsystems according to example 45.

Certain features that are described in this specification in the context of separate embodiments can also be implemented in combination or in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order show, or sequential order, to achieve desirable results. In certain implementations, multitasking and parallel processing may be advantageous. Nevertheless, it will be understood that various modifications may be made without departing from the spirit and scope of the claimed disclosure.

1. An impingement cooling device comprising:
a distributor plate including an upstream side, a downstream side opposite the upstream side, and a plurality of injection ports extending through the distributor plate from the upstream side to the downstream side; and
an impingement target plate including an upstream side, a downstream side opposite the upstream side, and a plurality of extraction ports extending through the impingement target plate from the upstream side to the downstream side;
wherein the plurality of injection ports are configured to accelerate a cooling fluid as the cooling fluid passes therethrough from the upstream side to the downstream side of the distributor plate;
wherein the impingement target plate is arranged adjacent the distributor plate such that the accelerated cooling fluid is directed onto the upstream side of the impingement target plate and thereafter through the extraction ports to the downstream side of the impingement target plate; and
wherein the upstream side of the impingement target plate and/or at least one extraction port in the plurality of extraction ports is provided with a plurality of protrusions configured to increase a conductive surface area of the upstream side of the impingement target plate and/or a conductive surface area within the at least one extraction port in the plurality of extraction ports, respectively.

2. The impingement cooling device of claim 1, wherein a subset of protrusions in the plurality of protrusions on the upstream side of the impingement target plate and/or in the at least one extraction port have micro-scale dimensions.

3. The impingement cooling device of claim 2, wherein the micro-scale protrusions on the upstream side of the impingement target plate are elliptical in cross section.

4. The impingement cooling device of claim 3, wherein a subset of the micro-scale protrusions on the upstream side of the impingement target plate each have a major axis that is aligned radially with respect to a given extraction port in the plurality of extraction ports.

5. The impingement cooling device of claim 3, wherein the micro-scale protrusions on the upstream side of the impingement target plate project from the upstream side of the impingement target plate at various heights.

6. The impingement cooling device of claim 5, wherein the injection ports have outlets on the downstream side of the distributor plate;
wherein the extraction ports have inlets on the upstream side of the impingement target plate; and
wherein the height of the micro-scale protrusions on the upstream side of the impingement target plate closest to the outlet of a given injection port in the plurality of injection ports is less than the height of the micro-scale protrusions on the upstream side of the impingement target plate closest to the inlet of a given extraction port in the plurality of extraction ports.

7. The impingement cooling device of claim 1, wherein the injection ports have outlets on the downstream side of the distributor plate;
wherein a subset of protrusions in the plurality of protrusions on the upstream side of the impingement target plate have port-scale dimensions similar to dimensions of the injection and extraction ports; and
wherein the port-scale protrusions on the upstream side of the impingement target plate are arranged about areas immediately opposite the outlets of respective injection ports in the plurality of injection ports such that the accelerated cooling fluid is directed onto the areas surrounded by the port-scale protrusions and then around the port-scale protrusions prior to being directed through the extraction ports.

8. The impingement cooling device of claim 7, wherein the port-scale protrusions have a curved diamond shape in cross section.

9. The impingement cooling device of claim 7, wherein a given extraction port is defined along first and second axes that are perpendicular to one another;
wherein a major axis of a first port-scale protrusion is aligned with the first axis of the given extraction port;
wherein a major axis of a second port-scale protrusion is aligned with the second axis of the given extraction port; and
wherein an elliptical flow path is defined between the first and second port-scale protrusions.

10. The impingement cooling device of claim 9, wherein micro-scale protrusions are formed within the elliptical flow path on the upstream side of the impingement target plate.

11. The impingement cooling device of claim 1, wherein a lip is provided on the downstream side of the impingement target plate adjacent an outlet of at least one extraction port in the plurality of extraction ports.

12. The impingement cooling device of claim 1, further comprising a baseplate, wherein the distributor plate and the impingement target plate are coupled to and project perpendicularly with respect to the baseplate.

13. The impingement cooling device of claim 12, wherein the baseplate comprises a vapor chamber or a heat pipe.

14. The impingement cooling device of claim 12, wherein the baseplate is configured to be situated over an integrated circuit.

15. (canceled)

16. The impingement cooling device of claim 12, wherein the distributor plate is a first distributor plate and the impingement target plate is a first impingement target plate, and further comprising:
a second distributor plate coupled to and projecting perpendicularly with respect to the baseplate, the second distributor plate including an upstream side, a downstream side opposite the upstream side, and a plurality of injection ports extending through the second distributor plate from the upstream side to the downstream side and configured to accelerate the cooling fluid as the cooling fluid passes therethrough from the upstream side to the downstream side of the second distributor plate; and
a second impingement target plate coupled to and projecting perpendicularly with respect to the baseplate, the second impingement target plate including an upstream side, a downstream side opposite the upstream side, and a plurality of extraction ports extending through the second impingement target plate from the upstream side to the downstream side;
wherein the second impingement target plate is arranged adjacent the second distributor plate such that the accelerated cooling fluid is directed onto the upstream side of the second impingement target plate and thereafter through the extraction ports to the downstream side of the second impingement target plate; and
wherein the first and second impingement target plates are arranged laterally beside one another with the downstream side of the first impingement target plate opposing the downstream side of the second impingement target plate so as to form an outlet channel therebetween.

17. The impingement cooling device of claim 16, further comprising conductive material spanning the outlet channel between the downstream side of the first impingement target plate and the downstream side of the second impingement target plate.

18. The impingement cooling device of claim 17, wherein the conductive material is formed as one or more of the following: cylindrical posts, rectangular fins, louver fins, metallic foam, and spun-like web material.

19. The impingement cooling device of claim 16, wherein the baseplate and the outlet channel extend in a longitudinal direction, and wherein the outlet channel varies in lateral width along the longitudinal direction.

20. The impingement cooling device of claim 16, further comprising:
a third distributor plate coupled to and projecting perpendicularly with respect to the baseplate, the third distributor plate including an upstream side, a downstream side opposite the upstream side, and a plurality of injection ports extending through the third distributor plate from the upstream side to the downstream side and configured to accelerate the cooling fluid as the cooling fluid passes therethrough from the upstream side to the downstream side of the third distributor plate; and
a third impingement target plate coupled to and projecting perpendicularly with respect to the baseplate, the third impingement target plate including an upstream side, a downstream side opposite the upstream side, and a plurality of extraction ports extending through the third impingement target plate from the upstream side to the downstream side;
wherein the third impingement target plate is arranged adjacent the third distributor plate such that the accelerated cooling fluid is directed onto the upstream side of the third impingement target plate and thereafter through the extraction ports to the downstream side of the third impingement target plate; and
wherein the second and third distributor plates are arranged laterally beside one another with the upstream side of the second distributor plate opposing the upstream side of the third distributor plate so as to form an inlet channel therebetween.

21. The impingement cooling device of claim 20, further comprising an inlet manifold coupled to the inlet channel and an outlet manifold coupled to the outlet channel;
wherein the inlet manifold is configured to provide the cooling fluid from a cooling fluid source to the inlet channel; and
wherein the outlet manifold is configured to provide the cooling fluid from the outlet channel to an exhaust area.

22-48. (canceled)
